(19) United States
(12) Patent Application Publication
(10) Pub. No.: US 2026/0114275 A1
(43) Pub. Date: Apr. 23, 2026

(54) STACKED SEMICONDUCTOR PACKAGE AND METHOD OF FABRICATING THE SAME

(71) Applicant: SAMSUNG ELECTRONICS CO., LTD., Suwon-si (KR)

(72) Inventors: SEONGHYEON PARK, Suwon-si (KR); PIL-KYU KANG, Suwon-si (KR); JAE-WHA PARK, Suwon-si (KR); EUNSUK JUNG, Suwon-si (KR); BYEONGGUK KO, Suwon-si (KR); KYUNGSEOK OH, Suwon-si (KR)

(73) Assignee: SAMSUNG ELECTRONICS CO., LTD., Suwon-si (KR)

(21) Appl. No.: 19/196,068

(22) Filed: May 1, 2025

(30) Foreign Application Priority Data
Oct. 23, 2024 (KR) 10-2024-0146169

(51) Int. Cl. H01L 23/373; H01L 23/00; H01L 23/31; H01L 25/00; H01L 25/07

(52) U.S. Cl. CPC H10W 40/255; H10W 74/121; H10W 90/00; H10W 90/26; H10W 90/297; H10W 90/792

(57) ABSTRACT

Provided is a semiconductor package including: a substrate; a first semiconductor chip on the substrate; a first dielectric layer on the substrate and at least partially surrounding the first semiconductor chip; a first passivation layer on a top surface of the first semiconductor chip and a top surface of the first dielectric layer; a second semiconductor chip on the first passivation layer; a first etch-stop layer on a top surface of the first passivation layer and on a top surface and a lateral surface of the second semiconductor chip; and a second dielectric layer on the first etch-stop layer and at least partially surrounding the second semiconductor chip, wherein a thermal expansion coefficient of the first dielectric layer is less than a thermal expansion coefficient of the substrate, and wherein a thermal expansion coefficient of the second dielectric layer is greater than the thermal expansion coefficient of the substrate.

### CROSS-REFERENCE TO RELATED APPLICATION

This application claims priority to Korean Patent Application No. 10-2024-0146169 filed on Oct. 23, 2024 in the Korean Intellectual Property Office, the disclosure of which is hereby incorporated by reference in its entirety.

### BACKGROUND

### 1. Field

The present disclosure relates to a semiconductor package and a method of fabricating the same, and more particularly, to a stacked semiconductor package and a method of fabricating the same.

### 2. Description of Related Art

With the development of the electronics industry, electronic products have increasing demands for high performance, high speed, and compact size. To meet the trend, there has recently been developed a packaging technology in which a plurality of semiconductor chips are mounted in a single package.

Portable devices have been increasingly demanded in recent electronic product markets, and as a result, it has been ceaselessly required for reduction in size and weight of electronic parts mounted on the portable devices. In order to accomplish the reduction in size and weight of the electronic parts, there is need for technology to integrate a number of individual devices into a single package as well as technology to reduce individual sizes of mounting parts. In particular, semiconductor packages operated at high frequencies are required to have compactness and excellent electrical characteristics. As a large number of devices are arranged or stacked in a single package, various issues can arise.

### SUMMARY

Provided is a semiconductor package with increased structural stability and a method of fabricating the same.

According to an aspect of the disclosure, a semiconductor package includes: a substrate; a first semiconductor chip on the substrate; a first dielectric layer on the substrate and at least partially surrounding the first semiconductor chip; a first passivation layer on a top surface of the first semiconductor chip and a top surface of the first dielectric layer; a second semiconductor chip on the first passivation layer; a first etch-stop layer on a top surface of the first passivation layer and on a top surface and a lateral surface of the second semiconductor chip; and a second dielectric layer on the first etch-stop layer and at least partially surrounding the second semiconductor chip, wherein a thermal expansion coefficient of the first dielectric layer is less than a thermal expansion coefficient of the substrate, and wherein a thermal expansion coefficient of the second dielectric layer is greater than the thermal expansion coefficient of the substrate.

According to an aspect of the disclosure, a semiconductor package includes: a substrate; and a plurality of chip structures stacked on the substrate, wherein each of the plurality of chip structures includes: a first semiconductor chip; a first dielectric layer that at least partially surrounds the first semiconductor chip; a second semiconductor chip on the first semiconductor chip; a second dielectric layer on the first dielectric layer and at least partially surrounding the second semiconductor chip; and a first etch-stop layer between the second dielectric layer and the first dielectric layer, wherein the first dielectric layer includes silicon oxide (SiO), and wherein the second dielectric layer includes silicon nitride (SiN).

According to an aspect of the disclosure, a method of fabricating a semiconductor package includes: placing a first semiconductor chip on a substrate; forming on the substrate a first dielectric layer that at least partially surrounds the first semiconductor chip; placing a second semiconductor chip on the first semiconductor chip; forming a first etch-stop layer on a top surface of the second semiconductor chip and a top surface of the first dielectric layer; forming on the first etch-stop layer a second dielectric layer on the first semiconductor chip and the first dielectric layer; performing a thinning process on the second dielectric layer to expose the first etch-stop layer on the first semiconductor chip; placing a third semiconductor chip on the second semiconductor chip; forming a second etch-stop layer on a top surface and lateral surfaces of the third semiconductor chip and a top surface of the second dielectric layer; and forming on the second etch-stop layer a third dielectric layer on the second semiconductor chip and the second dielectric layer, wherein a thermal expansion coefficient of the first dielectric layer and a thermal expansion coefficient of the third dielectric layer are less than a thermal expansion coefficient of the substrate, and wherein a thermal expansion coefficient of the second dielectric layer is greater than the thermal expansion coefficient of the substrate.

The object of the present disclosure is not limited to the foregoing, and other objects which have not been mentioned above will be clearly understood to those skilled in the art from the following description.

### BRIEF DESCRIPTION OF THE DRAWINGS

The above and other aspects and features of certain embodiments of the present disclosure will be more apparent from the following description taken in conjunction with the accompanying drawings, in which:

FIGS. 1, 2, 3, 4, 5, 6 and 7 illustrate cross-sectional views showing a semiconductor package according to one or more embodiments of the present disclosure;

FIG. 8 illustrates a cross-sectional view showing a semiconductor module according to one or more embodiments of the present disclosure; and

FIGS. 9, 10, 11, 12, 13, 14, 15, 16, 17, 18, 19 and 20 illustrate cross-sectional views showing a method of fabricating a semiconductor package according to one or more embodiments of the present disclosure.

### DETAILED DESCRIPTION

The following will now describe a semiconductor package according to the present disclosure with reference to the accompanying drawings.

In the following description, like reference numerals refer to like elements throughout the specification.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As sued herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

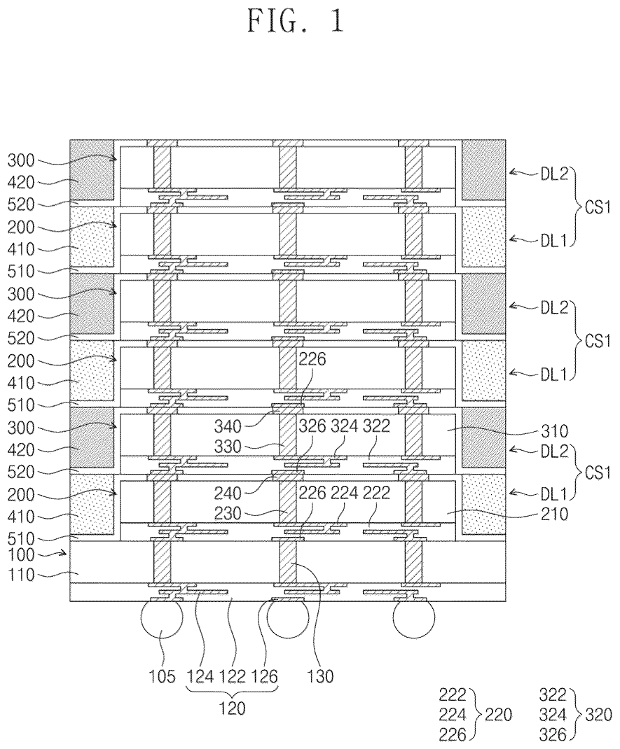

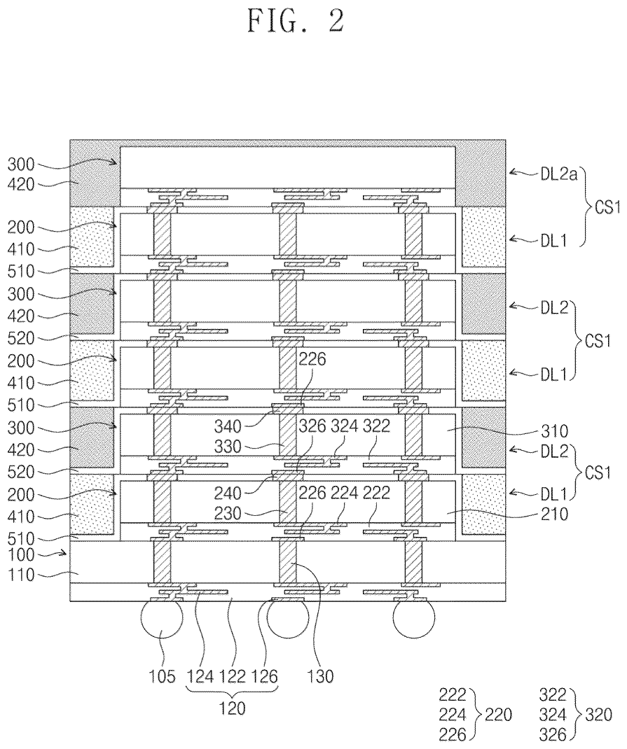

FIGS. 1 and 2 illustrate cross-sectional views showing a semiconductor package according to one or more embodiments of the present disclosure.

Referring to FIG. 1, a base substrate 100 may be provided. The base substrate 100 may be a semiconductor substrate. The base substrate 100 may include an integrated circuit therein. For example, the base substrate 100 may be a buffer semiconductor chip including an electronic device such as a transistor. For example, the base substrate 100 may be a wafer-level die formed of a semiconductor such as silicon (Si). FIG. 1 depicts that the base substrate 100 is a buffer semiconductor chip, but the present disclosure is not limited thereto. According to one or more embodiments, the base substrate 100 may be a semiconductor substrate including only a wiring pattern for vertical connection and redistribution. Alternatively, the base substrate 100 may be a substrate, such as printed circuit board, which does not include an electronic device such as a transistor. A silicon wafer may have a thickness less than that of a printed circuit board (PCB). The following will describe an example in which the base substrate 100 and a buffer semiconductor chip are the same component.

The buffer semiconductor chip 100 may be a logic chip. Alternatively, the buffer semiconductor chip 100 may be a memory chip, such as dynamic random access memory (DRAM), static random access memory (SRAM), magnetic random access memory (MRAM), or flash memory. The buffer semiconductor chip 100 may have a front surface and a rear surface. In this description, the language “front surface” may be defined to indicate an active surface of an integrated element in a semiconductor chip or a surface on which a plurality of pads of a semiconductor chip are formed, and the language “rear surface” may be defined to indicate an opposite surface that faces the front surface. A bottom surface of the buffer semiconductor chip 100 may be the front surface of the buffer semiconductor chip 100. For example, the buffer semiconductor chip 100 may be provided in a face-down state. The buffer semiconductor chip 100 may include a first base layer 110, a first circuit layer 120 provided on a front surface of the first base layer 110, and a first through via 130 that penetrates the first base layer 110.

The first base layer 110 may include silicon (Si). An integrated element or integrated circuits may be formed in a lower portion of the first base layer 110.

The first circuit layer 120 may be provided on a bottom surface of the first base layer 110. The first circuit layer 120 may be electrically connected to the integrated element or the integrated circuits formed in the first base layer 110. For example, the first circuit layer 120 may have a first circuit pattern 124 provided in the first dielectric pattern 122, and the first circuit pattern 124 may be coupled to the integrated element or the integrated circuits formed in the first base layer 110. A portion of the first circuit pattern 124 may be exposed on a bottom surface of the first circuit layer 120, and the exposed portion of the first circuit pattern 124 may correspond to a pad (referred to hereinafter as a first front pad 126) of the buffer semiconductor chip 100. The bottom surface of the buffer semiconductor chip 100 on which the first circuit layer 120 is provided may be an active surface of the buffer semiconductor chip 100.

The first through via 130 may vertically penetrate the first base layer 110. One end of the first through via 130 may be exposed on a top surface of the first base layer 110. The first through via 130 may be exposed on the top surface of the first base layer 110 or the rear surface of the buffer semiconductor chip 100. A top surface of the first through via 130 may be substantially flat and coplanar with a top surface of the first base layer 110. Another end of the first through via 130 may extend toward the front surface of the buffer semiconductor chip 100 to come into contact with the first circuit layer 120. The first through via 130 may be coupled to the first circuit pattern 124 of the first circuit layer 120. The first through via 130 may be provided in plural. The first through via 130 may include a metallic material such as copper (Cu) or tungsten (W).

A dielectric layer may be provided as needed to surround the first through via 130. For example, the dielectric layer may include at least one selected from silicon oxide (SiO), silicon nitride (SiN), silicon oxynitride (SiON), and low-k dielectric.

The buffer semiconductor chip 100 may further include a lower protective layer. The lower protective layer may be disposed on the bottom surface of the buffer semiconductor chip 100, covering the first circuit layer 120. The lower protective layer may protect the first circuit layer 120. The lower protective layer may expose the first front pad 126. The lower protective layer may include a dielectric polymer or a photo-imageable dielectric (PID).

According to one or more embodiments, the buffer semiconductor chip 100 may include a first backside pad provided on the top surface of the first base layer 110. On the top surface of the first base layer 110, the first backside pad may be connected to the first through via 130. The following description will focus on the embodiment of FIG. 1.

External terminals 105 may be provided on a bottom surface of the first front pad 126. The external terminals 105 may include solder balls or solder bumps, and based on type and arrangement of the external terminals 105, a semiconductor package may be provided in the form of one of a ball grid array (BGA) type, a fine ball-grid array (FBGA) type, and a land grid array (LGA) type.

First chip structures CS1 may be stacked on the buffer semiconductor chip 100. Each of the first chip structures CS1 may include a first device layer DL1 and a second device layer DL2 stacked on the first device layer DL1.

The first device layer DL1 may include a first semiconductor chip 200, a first dielectric layer 410, and a first etch-stop layer 510.

The first semiconductor chip 200 may be disposed on the buffer semiconductor chip 100. A width of the first semiconductor chip 200 may be less than that of the buffer semiconductor chip 100. The first semiconductor chip 200 may be disposed on a central portion of the buffer semiconductor chip 100. The first semiconductor chip 200 may be spaced apart from lateral surfaces of the buffer semiconductor chip 100. A bottom surface of the first semiconductor chip 200 may be in contact with a top surface of an underlying other first chip structure CS1. Alternatively, a bottom surface of the first semiconductor chip 200 in a lowermost one of the first chip structures CS1 may be in contact with the top surface of the buffer semiconductor chip 100. The bottom surface of the first semiconductor chip 200 may be a front surface of the first semiconductor chip 200. For example, the first semiconductor chip 200 may be provided in a face-down state on the buffer semiconductor chip 100. The first semiconductor chip 200 may be of the same type as that of the buffer semiconductor chip 100. For example, the first semiconductor chips 200 may be a memory chip. The first semiconductor chip 200 may include a second base layer 210, a second circuit layer 220 provided on a front surface of the second base layer 210, a second through via 230 that penetrates the second base layer 210, and a second backside pad 240.

The second base layer 210 may include silicon (Si). An integrated element or integrated circuits may be formed in a lower portion of the second base layer 210.

The second circuit layer 220 may be provided on a bottom surface of the second base layer 210. The second circuit layer 220 may be electrically connected to the integrated element or the integrated circuits formed in the second base layer 210. For example, the second circuit layer 220 may have a second circuit pattern 224 provided in the second dielectric pattern 222, and the second circuit pattern 224 may be coupled to the integrated element or the integrated circuits formed in the second base layer 210. A portion of the second circuit pattern 224 may be exposed on a bottom surface of the second circuit layer 220, and the exposed portion of the second circuit pattern 224 may correspond to a pad (referred to hereinafter as a second front pad 226) of the first semiconductor chip 200. A bottom surface of the second front pad 226 may be substantially flat and coplanar with the bottom surface of the second circuit layer 220. The bottom surface of the first semiconductor chip 200 on which the second circuit layer 220 is provided may be an active surface of the first semiconductor chip 200.

The second through via 230 may vertically penetrate the second base layer 210. One end of the second through via 230 may be exposed on a top surface of the second base layer 210. The second through via 230 may be exposed on the top surface of the second base layer 210 or a rear surface of the first semiconductor chip 200. A top surface of the second through via 230 may be substantially flat and coplanar with the top surface of the second base layer 210. Another end of the second through via 230 may extend toward the front surface of the first semiconductor chip 200, contacting the second circuit layer 220. The second through via 230 may be coupled to the second circuit pattern 224 of the second circuit layer 220. The second through via 230 may be provided in plural. The second through via 230 may include a metallic material such as copper (Cu) or tungsten (W).

A dielectric layer may be provided as needed to surround the second through via 230. For example, the dielectric layer may include at least one selected from silicon oxide (SiO), silicon nitride (SiN), silicon oxynitride (SiON), and low-k dielectric.

The second backside pad 240 may be disposed on the top surface of the second base layer 210. The second backside pad 240 may protrude onto the top surface of the second base layer 210. On the top surface of the second base layer 210, the second backside pad 240 may be connected to the second through via 230. When the second through via 230 is provided in plural, the second backside pad 240 may also be provided in plural, and each of the second backside pads 240 may be connected to one of the second through vias 230. The second backside pad 240 may include a metallic material such as copper (Cu).

The first semiconductor chip 200 may further include a lower protective layer. The lower protective layer may be disposed on the bottom surface of the first semiconductor chip 200, covering the second circuit layer 220. The lower protective layer may protect the second circuit layer 220. The lower protective layer may expose the second front pad 226. The lower protective layer may include silicon oxide (SiO), silicon nitride (SiN), silicon oxynitride (SiON), or silicon carbonitride (SiCN). When the first semiconductor chip 200 includes the lower protective layer, a bottom surface of the lower protective layer and the bottom surface of the second front pad 226 may be substantially flat and coplanar with each other. The lower protective layer may be omitted if necessary.

The first etch-stop layer 510 may conformally cover lateral surfaces and a top surface of the first semiconductor chip 200. The second backside pad 240 of the first semiconductor chip 200 may penetrate the first etch-stop layer 510. On the top surface of the first semiconductor chip 200, the second backside pad 240 may be exposed on a top surface of the first etch-stop layer 510. A top surface of the second backside pad 240 may be substantially flat and coplanar with a top surface of the first etch-stop layer 510. The first etch-stop layer 510 may extend from the lateral surfaces of the first semiconductor chip 200 onto the top surface of an underlying other first chip structure CS1. For example, the first etch-stop layer 510 may conformally cover the lateral surfaces and the top surface of the first semiconductor chip 200 and the top surface of an underlying first chip structure CS1. Alternatively, the first etch-stop layer 510 of the lowermost one of the first chip structures CS1 may extend from the lateral surfaces of the first semiconductor chip 200 onto the top surface of the buffer semiconductor chip 100. For example, the first etch-stop layer 510 may conformally cover the lateral surfaces and the top surface of the first semiconductor chip 200 and the top surface of the buffer semiconductor chip 100. A bottom surface of the first etch-stop layer 510 may be substantially flat and coplanar with the bottom surface of the first semiconductor chip 200. The first etch-stop layer 510 may include a material having an etch selectivity with respect to the first dielectric layer 410 which will be discussed below. Alternatively, the first etch-stop layer 510 may include a material different from that of the first dielectric layer 410. For example, the first etch-stop layer 510 may include silicon nitride (SiN).

The first dielectric layer 410 may be disposed adjacent to the lateral surfaces of the first semiconductor chip 200. For example, on the first etch-stop layer 510, the first dielectric layer 410 may surround the first semiconductor chip 200. The first dielectric layer 410 may cover the lateral surfaces of the first semiconductor chip 200. On the first semiconductor chip 200, the first dielectric layer 410 may expose the top surface of the first etch-stop layer 510. A top surface of the first dielectric layer 410 may be substantially flat and coplanar with the top surface of the first etch-stop layer 510. A width of the first dielectric layer 410 may be the same as that of the buffer semiconductor chip 100. Lateral surfaces of the first dielectric layer 410 may be vertically aligned with those of the buffer semiconductor chip 100. The first dielectric layer 410 may include a dielectric material. The first dielectric layer 410 may have a thermal expansion coefficient less than that of the buffer semiconductor chip 100. For example, when the buffer semiconductor chip 100 is a semiconductor chip formed of silicon (Si), the first dielectric layer 410 may include silicon oxide (SiO).

The second device layer DL2 may be disposed on the first device layer DL1. A bottom surface of the second device layer DL2 may be in contact with a top surface of the first device layer DL1. The second device layer DL2 may include a second semiconductor chip 300, a second dielectric layer 420, and a second etch-stop layer 520.

The second semiconductor chip 300 may be disposed on the first semiconductor chip 200. A width of the second semiconductor chip 300 may be the same as or similar to that of the first semiconductor chip 200. The width of the second semiconductor chip 300 may be less than that of the buffer semiconductor chip 100. The second semiconductor chip 300 may be vertically aligned with the first semiconductor chip 200. For example, the second semiconductor chip 300 may be disposed on the central portion of the buffer semiconductor chip 100. A bottom surface of the second semiconductor chip 300 may be in contact with the top surface of the first semiconductor chip 200. The bottom surface of the second semiconductor chip 300 may be a front surface of the second semiconductor chip 300. For example, the second semiconductor chip 300 may be provided in a face-down state on the first semiconductor chip 200. The second semiconductor chip 300 may be of the same type as that of the first semiconductor chip 200. For example, the second semiconductor chips 300 may be a memory chip. The second semiconductor chip 300 may have a configuration the same as or similar to that of the first semiconductor chip 200. The second semiconductor chip 300 may include a third base layer 310, a third circuit layer 320 provided on a front surface of the third base layer 310, a third through via 330 that penetrates the third base layer 310, and a third backside pad 340.

The third base layer 310 may include silicon (Si). An integrated element or integrated circuits may be formed in a lower portion of the third base layer 310.

The third circuit layer 320 may be provided on a bottom surface of the third base layer 310. The third circuit layer 320 may be electrically connected to the integrated element or the integrated circuits formed in the third base layer 310. For example, the third circuit layer 320 may have a third circuit pattern 324 provided in the third dielectric pattern 322, and the third circuit pattern 324 may be coupled to the integrated element or the integrated circuits formed in the third base layer 310. A portion of the third circuit pattern 324 may be exposed on a bottom surface of the third circuit layer 320, and the exposed portion of the third circuit pattern 324 may correspond to a pad (referred to hereinafter as a third front pad 326) of the second semiconductor chip 300. A bottom surface of the third front pad 326 may be substantially flat and coplanar with the bottom surface of the third circuit layer 320. The bottom surface of the second semiconductor chip 300 on which the third circuit layer 320 is provided may be an active surface of the second semiconductor chip 300.

The third through via 330 may vertically penetrate the third base layer 310. One end of the third through via 330 may be exposed on a top surface of the third base layer 310. The third through via 330 may be exposed on the top surface of the third base layer 310 or a rear surface of the second semiconductor chip 300. A top surface of the third through via 330 may be substantially flat and coplanar with the top surface of the third base layer 310. Another end of the third through via 330 may extend toward the front surface of the second semiconductor chip 300, contacting the third circuit layer 320. The third through via 330 may be coupled to the third circuit pattern 324 of the third circuit layer 320. The third through via 330 may be provided in plural. The third through via 330 may include a metallic material such as copper (Cu) or tungsten (W).

A dielectric layer may be provided as needed to surround the third through via 330. For example, the dielectric layer may include at least one selected from silicon oxide (SiO), silicon nitride (SiN), silicon oxynitride (SiON), and low-k dielectric.

The third backside pad 340 may be disposed on the top surface of the third base layer 310. The third backside pad 340 may protrude onto the top surface of the third base layer 310. On the top surface of the third base layer 310, the third backside pad 340 may be connected to the third through via 330. When the third through via 330 is provided in plural, the third backside pad 340 may also be provided in plural, and each of the third backside pads 340 may be connected to one of the third through vias 330. The third backside pad 340 may include a metallic material such as copper (Cu).

The second semiconductor chip 300 may further include a lower protective layer. The lower protective layer may be disposed on the bottom surface of the second semiconductor chip 300, covering the third circuit layer 320. The lower protective layer may protect the third circuit layer 320. The lower protective layer may expose the third front pad 326. The lower protective layer may include silicon oxide (SiO), silicon nitride (SiN), silicon oxynitride (SiON), or silicon carbonitride (SiCN). When the second semiconductor chip 300 includes the lower protective layer, a bottom surface of the lower protective layer and the bottom surface of the third front pad 326 may be substantially flat and coplanar with each other. The lower protective layer may be omitted, if necessary.

The second etch-stop layer 520 may conformally cover lateral surfaces and a top surface of the second semiconductor chip 300. The third backside pad 340 of the second semiconductor chip 300 may penetrate the second etch-stop layer 520. On the top surface of the second semiconductor chip 300, the third backside pad 340 may be exposed on a top surface of the second etch-stop layer 520. A top surface of the third backside pad 340 may be substantially flat and coplanar with the top surface of the second etch-stop layer 520. The second etch-stop layer 520 may extend from the lateral surfaces of the second semiconductor chip 300 onto the top surface of the first dielectric layer 410. For example, the second etch-stop layer 520 may conformally the lateral surfaces and the top surface of the first semiconductor chip 200 and the top surface of the first dielectric layer 410. A bottom surface of the second etch-stop layer 520 may be substantially flat and coplanar with the bottom surface of the second semiconductor chip 300. The second etch-stop layer 520 may include a material having an etch selectivity with respect to the second dielectric layer 420 which will be discussed below. Alternatively, the second etch-stop layer 520 may include a material different from that of the second dielectric layer 420. For example, the second etch-stop layer 520 may include silicon oxide (SiO).

The second dielectric layer 420 may be disposed adjacent to the lateral surfaces of the second semiconductor chip 300. For example, on the second etch-stop layer 520, the second dielectric layer 420 may surround the second semiconductor chip 300. The second dielectric layer 420 may cover the lateral surfaces of the second semiconductor chip 300. On the second semiconductor chip 300, the second dielectric layer 420 may expose the top surface of the second etch-stop layer 520. A top surface of the second dielectric layer 420 may be substantially flat and coplanar with the top surface of the second etch-stop layer 520. A width of the second dielectric layer 420 may be the same as that of the buffer semiconductor chip 100. Lateral surfaces of the second dielectric layer 420 may be vertically aligned with those of the buffer semiconductor chip 100. The second dielectric layer 420 may include a dielectric material. The second dielectric layer 420 may have a thermal expansion coefficient greater than that of the buffer semiconductor chip 100. For example, when the buffer semiconductor chip 100 is a semiconductor chip formed of silicon (Si), the second dielectric layer 420 may include silicon nitride (SiN).

A bottom surface of the second device layer DL2 may be in contact with a top surface of the first device layer DL1. The bottom surface of the second etch-stop layer 520 in the second device layer DL2 may be in contact with the top surface of the first dielectric layer 410 in the first device layer DL1. The bottom surface of the second semiconductor chip 300 in the second device layer DL2 may be in contact with the top surface of the first etch-stop layer 510 in the first device layer DL1.

The second semiconductor chip 300 may be mounted on the first semiconductor chip 200. For example, the second semiconductor chip 300 may be disposed on the first semiconductor chip 200. The second semiconductor chip 300 may be disposed in a face-down state on the first semiconductor chip 200. The second backside pad 240 of the first semiconductor chip 200 may be vertically aligned with the third front pad 326 of the second semiconductor chip 300. The first device layer DL1 and the second device layer DL2 may be in contact with each other to connect the second backside pad 240 and the third front pad 326 to each other.

The second semiconductor chip 300 may be connected to the first semiconductor chip 200. On an interface between the first device layer DL1 and the second device layer DL2, the second backside pad 240 of the first semiconductor chip 200 may be bonded to the third front pad 326 of the second semiconductor chip 300. In this configuration, the second backside pad 240 and the third front pad 326 may constitute an intermetallic hybrid bonding. In this description, the term “hybrid bonding” may denote a bonding in which two components of the same kind are merged at an interface therebetween. For example, the second backside pad 240 and the third front pad 326 bonded to each other may have a continuous configuration, and an invisible interface may be present between the second backside pad 240 and the third front pad 326. For example, the second backside pad 240 and the third front pad 326 may be formed of the same material, and no interface may be present between the second backside pad 240 and the third front pad 326. The second backside pad 240 and the third front pad 326 may be provided as one component. For example, the second backside pad 240 and the third front pad 326 may be bonded to each other to constitute a single unitary piece.

Neighboring first chip structures CS1 may be in contact with each other. The bottom surface of the first etch-stop layer 510 in an overlying first chip structure CS1 may be in contact with the top surface of the second dielectric layer 420 in an underlying first chip structure CS1. The bottom surface of the first semiconductor chip 200 in an overlying first chip structure CS1 may be in contact with the top surface of the second etch-stop layer 520 in an underlying first chip structure CS1.

Neighboring first chip structures CS1 may be connected to each other. For example, the third backside pad 340 of the second semiconductor chip 300 in an underlying first chip structure CS1 may be vertically aligned with the second front pad 226 of the first semiconductor chip 200 in an overlying first chip structure CS1. Neighboring first chip structures CS1 may be in contact with each other to connect the third backside pad 340 and the second front pad 226 to each other.

On an interface between the first chip structures CS1, the third backside pad 340 of the second semiconductor chip 300 in an underlying first chip structure CS1 may be bonded to the second front pad 226 of the first semiconductor chip 200 in an overlying first chip structure CS1. In this configuration, the third backside pad 340 and the second front pad 226 may constitute an intermetallic hybrid bonding. For example, the third backside pad 340 and the second front pad 226 coupled to each other may have a continuous configuration, and an invisible interface may be present between the third backside pad 340 and the second front pad 226. The third backside pad 340 and the second front pad 226 may be formed of the same material, and no interface may be present between the third backside pad 340 and the second front pad 226. For example, the third backside pad 340 and the second front pad 226 may be bonded to each other to constitute a single unitary piece.

FIG. 1 shows three first chip structures CS1 stacked on the buffer semiconductor chip 100, but the present disclosure is not limited thereto. According to one or more embodiments, two or four or more first chip structures CS1 may be provided as needed. In addition, according to one or more embodiments, when the first chip structure CS1 is provided in plural, an uppermost one of the first chip structures CS1 may include only first device layer DL1 without having the second device layer DL2. The following description will focus on the embodiment of FIG. 1.

The first device layer DL1 of the lowermost first chip structure CS1 may be in contact with the buffer semiconductor chip 100. The bottom surface of each of the first etch-stop layer 510 and the first semiconductor chip 200 in the lowermost first chip structure CS1 may be in contact with the top surface of the buffer semiconductor chip 100.

On an interface between the lowermost first chip structure CS1 and the buffer semiconductor chip 100, the first through via 130 of the buffer semiconductor chip 100 may be bonded to the second front pad 226 of the first semiconductor chip 200 in the lowermost first chip structure CS1. In this configuration, the first through via 130 and the second front pad 226 may constitute an intermetallic hybrid bonding. For example, the first through via 130 and the second front pad 226 bonded to each other may have a continuous configuration, and an invisible interface may be present between the first through via 130 and the second front pad 226. The first through via 130 and the second front pad 226 may be formed of the same material, and no interface may be present between the first through via 130 and the second front pad 226. For example, the first through via 130 and the second front pad 226 may be bonded to each other to constitute a single unitary piece.

According to one or more embodiments of the present disclosure, the first dielectric layer 410 of the first device layer DL1 disposed on the buffer semiconductor chip 100 may have a thermal expansion coefficient less than that of the buffer semiconductor chip 100. A difference in thermal expansion coefficient between the first dielectric layer 410 and the buffer semiconductor chip 100 may induce a concave smile-shaped warpage of a semiconductor package. The second dielectric layer 420 of the second device layer DL2 disposed on the buffer semiconductor chip 100 may have a thermal expansion coefficient greater than that of the buffer semiconductor chip 100. A difference in thermal expansion coefficient between the second dielectric layer 420 and the buffer semiconductor chip 100 may induce a convex crying-shaped warpage of a semiconductor package. The first dielectric layer 410, which has a thermal expansion coefficient less than that of the buffer semiconductor chip 100, and the second dielectric layer 420, which has a thermal expansion coefficient greater than that of the buffer semiconductor chip 100, may be alternately stacked on the buffer semiconductor chip 100, and it may thus be possible to suppress warpage of a semiconductor package. As a result, a semiconductor package may have increased structural stability.

FIG. 1 depicts that the first chip structures CS1 having the same configuration are stacked on the buffer semiconductor chip 100, but the present disclosure is not limited thereto. As shown in FIG. 2, a second device layer DL2a of the uppermost first chip structure CS1 may have a configuration partially different from those of remaining second device layers DL2. For example, the second semiconductor chip 300 of the uppermost second device layer DL2a may not include any of the third through via 330 and the third backside pad 340. The uppermost second device layer DL2a may not include the second etch-stop layer 520. The second dielectric layer 420 of the uppermost second device layer DL2a may cover a top surface of the second semiconductor chip 300. According to one or more embodiments, the uppermost second device layer DL2a may include at least one selected from the second etch-stop layer 520, the second dielectric layer 420, the third through via 330, and the third backside pad 340.

In the embodiments that follow, a detailed description of technical features repetitive to those discussed above with reference to FIGS. 1 and 2 will be omitted, and a difference thereof will be discussed in detail. The same reference numerals may be allocated to the same components as those of the semiconductor package discussed above according to one or more embodiments of the present disclosure.

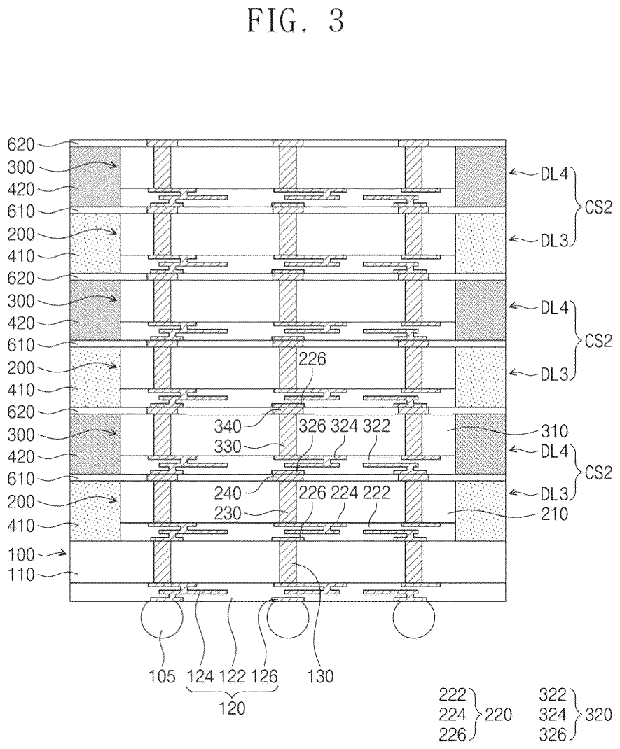

FIG. 3 illustrates a cross-sectional view showing a semiconductor package according to one or more embodiments of the present disclosure.

Referring to FIG. 3, a buffer semiconductor chip 100 may be provided. The buffer semiconductor chip 100 may be the same as or similar to the buffer semiconductor chip 100 discussed with reference to FIGS. 1 and 2.

Second chip structures CS2 may be stacked on the buffer semiconductor chip 100. Each of the second chip structures CS2 may include a third device layer DL3 and a fourth device layer DL4 stacked on the third device layer DL3.

The third device layer DL3 may have a configuration similar to that of the first device layer DL1 discussed with reference to FIGS. 1 and 2. In comparison with the first device layer DL1, the third device layer DL3 may have a first passivation layer 610 in place of the first etch-stop layer 510. The third device layer DL3 may include a first semiconductor chip 200, a first dielectric layer 410, and the first passivation layer 610.

The first semiconductor chip 200 may be provided. The first semiconductor chip 200 may be the same as or similar to the first semiconductor chip 200 discussed with reference to FIGS. 1 and 2.

The first dielectric layer 410 may surround the first semiconductor chip 200. The first dielectric layer 410 may cover lateral surfaces of the first semiconductor chip 200. A top surface of the first dielectric layer 410 may be substantially flat and coplanar with the top surface of the first semiconductor chip 200. A bottom surface of the first dielectric layer 410 may be substantially flat and coplanar with the bottom surface of the first semiconductor chip 200. The first dielectric layer 410 may have a thermal expansion coefficient less than that of the buffer semiconductor chip 100. For example, when the buffer semiconductor chip 100 is a semiconductor chip formed of silicon (Si), the first dielectric layer 410 may include silicon oxide (SiO).

The first passivation layer 610 may be disposed on the first semiconductor chip 200 and the first dielectric layer 410. The first passivation layer 610 may cover the top surface of the first semiconductor chip 200 and the top surface of the first dielectric layer 410. A bottom surface of the first passivation layer 610 may be in contact with the top surface of the first semiconductor chip 200 and the top surface of the first dielectric layer 410. A second backside pad 240 of the first semiconductor chip 200 may penetrate the first passivation layer 610. The second backside pad 240 may be exposed on a top surface of the first passivation layer 610. A top surface of the second backside pad 240 may be substantially flat and coplanar with the top surface of the first passivation layer 610. The first passivation layer 610 may include a material different from that of the first dielectric layer 410. For example, the first passivation layer 610 may include a dielectric polymer, photo-imageable dielectric (PID), or silicon nitride (SiN).

The fourth device layer DL4 may be disposed on the third device layer DL3. A bottom surface of the fourth device layer DL4 may be in contact with a top surface of the third device layer DL3. The fourth device layer DL4 may have a configuration similar to that of the second device layer DL2 discussed with reference to FIGS. 1 and 2. In comparison with the second device layer DL2, the fourth device layer DL4 may have a second passivation layer 620 in place of the second etch-stop layer 520. The fourth device layer DL4 may include a second semiconductor chip 300, a second dielectric layer 420, and the second passivation layer 620.

Above the first semiconductor chip 200, the second semiconductor chip 300 may be disposed on the first passivation layer 610. The second semiconductor chip 300 may be the same as or similar to the second semiconductor chip 300 discussed with reference to FIGS. 1 and 2.

On the first passivation layer 610, the second dielectric layer 420 may surround the second semiconductor chip 300. The second dielectric layer 420 may cover lateral surfaces of the second semiconductor chip 300. A top surface of the second dielectric layer 420 may be substantially flat and coplanar with the top surface of the second semiconductor chip 300. A bottom surface of the second dielectric layer 420 may be substantially flat and coplanar with the bottom of the second semiconductor chip 300. The second dielectric layer 420 may have a thermal expansion coefficient greater than that of the buffer semiconductor chip 100. For example, when the buffer semiconductor chip 100 is a semiconductor chip formed of silicon (Si), the second dielectric layer 420 may include silicon nitride (SiN).

The second passivation layer 620 may be disposed on the second semiconductor chip 300 and the second dielectric layer 420. The second passivation layer 620 may cover the top surface of the second semiconductor chip 300 and the top surface of the second dielectric layer 420. A bottom surface of the second passivation layer 620 may be in contact with the top surface of the second semiconductor chip 300 and the top surface of the second dielectric layer 420. A third backside pad 340 of the second semiconductor chip 300 may penetrate the second passivation layer 620. The third backside pad 340 may be exposed on a top surface of the second passivation layer 620. A top surface of the third backside pad 340 may be substantially flat and coplanar with the top surface of the second passivation layer 620. The second passivation layer 620 may include a material different from that of the second dielectric layer 420. For example, the second passivation layer 620 may include a dielectric polymer, photo-imageable dielectric (PID), or silicon oxide (SiO).

A bottom surface of the fourth device layer DL4 may be in contact with a top surface of the third device layer DL3. The bottom surface of each of the second dielectric layer 420 and the second semiconductor chip 300 in the fourth device layer DL4 may be in contact with the top surface of the first passivation layer 610 in the third device layer DL3.

The second semiconductor chip 300 may be mounted on the first semiconductor chip 200. The second backside pad 240 of the first semiconductor chip 200 may be vertically aligned with the third front pad 326 of the second semiconductor chip 300. The third device layer DL3 and the fourth device layer DL4 may be in contact with each other to connect second backside pad 240 and the third front pad 326 to each other. The second backside pad 240 and the third front pad 326 may constitute an intermetallic hybrid bonding.

Neighboring second chip structures CS2 may be in contact with each other. The bottom surface of the first dielectric layer 410 and the bottom surface of the first semiconductor chip 200 in an overlying second chip structure CS2 may be in contact with the top surface of the second passivation layer 620 in an underlying second chip structure CS2.

Neighboring second chip structures CS2 may be connected to each other. For example, the third backside pad 340 of the second semiconductor chip 300 in an underlying second chip structure CS2 may be vertically aligned with the second front pad 226 of the first semiconductor chip 200 in an overlying second chip structure CS2. Neighboring second chip structures CS2 may be in contact with each other to connect the third backside pad 340 and the second front pad 226 to each other. The third backside pad 340 and the second front pad 226 may constitute an intermetallic hybrid bonding.

On an interface between a lowermost second chip structure CS2 and the buffer semiconductor chip 100, the first through via 130 of the buffer semiconductor chip 100 may be bonded to the second front pad 226 of the first semiconductor chip 200 in the lower second chip structure CS2. In this configuration, the first through via 130 and the second front pad 226 may constitute an intermetallic hybrid bonding.

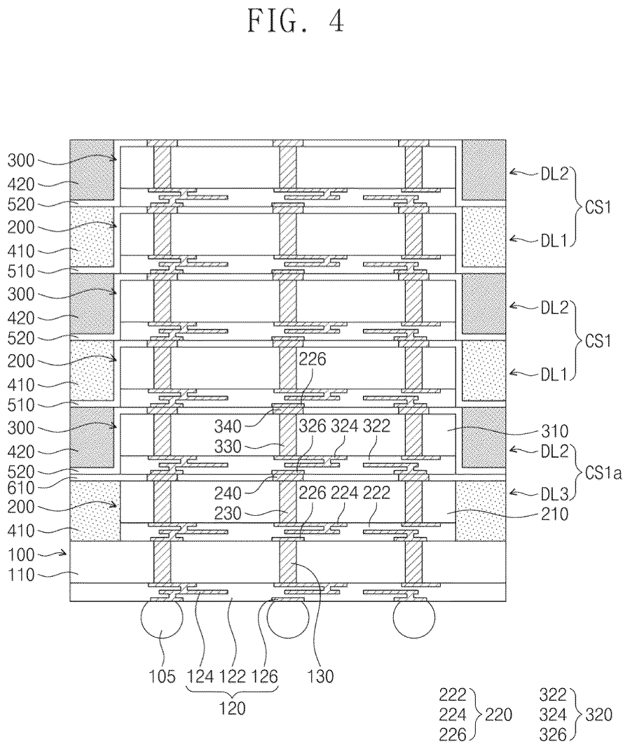

FIG. 4 illustrates a cross-sectional view showing a semiconductor package according to one or more embodiments of the present disclosure.

Referring to FIG. 4, first chip structures CS1a and CS1 may be stacked on the buffer semiconductor chip 100. A lowermost first chip structure CS1a may have a configuration partially different from those of remaining first chip structures CS1.

The first chip structures CS1 other than the lowermost first chip structure CS1a may have their configurations the same as or similar to those of the first chip structures CS1 discussed with reference to FIGS. 1 and 2.

In place of the first device layer DL1, the third device layer DL3 discussed with reference to FIG. 3 may be included in the lowermost first chip structure CS1a. For example, the lowermost first chip structure CS1a may include a third device layer DL3 and a second device layer DL2 disposed in the third device layer DL3.

The third device layer DL3 of the lowermost first chip structure CS1a may include a first semiconductor chip 200, a first dielectric layer 410, and a first passivation layer 610.

The second device layer DL2 of the lowermost first chip structure CS1a may be disposed on the third device layer DL3. The second device layer DL2 may include a second semiconductor chip 300, a second dielectric layer 420, and a second etch-stop layer 520.

The second device layer DL2 of the lowermost first chip structure CS1a may have a bottom surface in contact with a top surface of the third device layer DL3. The second etch-stop layer 520 and the second semiconductor chip 300 of the second device layer DL2 may have their bottom surfaces in contact with a top surface of the first passivation layer 610.

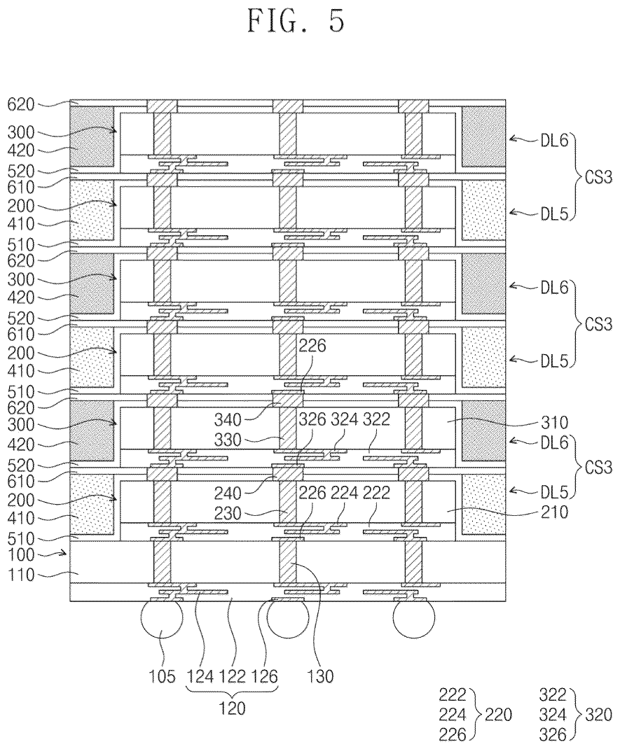

FIG. 5 illustrates a cross-sectional view showing a semiconductor package according to one or more embodiments of the present disclosure.

Referring to FIG. 5, a buffer semiconductor chip 100 may be provided.

Third chip structures CS3 may be stacked on the buffer semiconductor chip 100. Each of the third chip structures CS3 may include a fifth device layer DL5 and a sixth device layer DL6 stacked on the fifth device layer DL5.

The fifth device layer DL5 may have a configuration similar to that of the first device layer DL1 discussed with reference to FIGS. 1 and 2. In comparison with the first device layer DL1, the fifth device layer DL5 may further include a first passivation layer 610. The fifth device layer DL5 may include a first semiconductor chip 200, a first dielectric layer 410, a first etch-stop layer 510, and the first passivation layer 610.

The first semiconductor chip 200 may be provided. The first etch-stop layer 510 may conformally cover lateral surfaces and a top surface of the first semiconductor chip 200 and a top surface of an underlying third chip structure CS3. Alternatively, the first etch-stop layer 510 of a lowermost one of the third chip structures CS3 may conformally cover the lateral surfaces and the top surface of the first semiconductor chip 200 and a top surface of the buffer semiconductor chip 100. On the first etch-stop layer 510, the first dielectric layer 410 may surround the first semiconductor chip 200. A top surface of the first dielectric layer 410 may be substantially flat and coplanar with the top surface of the first etch-stop layer 510 positioned on the first semiconductor chip 200. The first dielectric layer 410 may have a thermal expansion coefficient less than that of the buffer semiconductor chip 100. The first passivation layer 610 may be disposed on the first semiconductor chip 200 and the first dielectric layer 410. The first passivation layer 610 may cover the top surface of the first dielectric layer 410. Above of the first semiconductor chip 200, the first passivation layer 610 may cover the top surface of the first etch-stop layer 510. A second backside pad 240 of the first semiconductor chip 200 may penetrate the first etch-stop layer 510 and the first passivation layer 610. The second backside pad 240 may be exposed on a top surface of the first passivation layer 610. A top surface of the second backside pad 240 may be substantially flat and coplanar with the top surface of the first passivation layer 610.

The sixth device layer DL6 may be disposed on the fifth device layer DL5. A bottom surface of the sixth device layer DL6 may be in contact with a top surface of the fifth device layer DL5. The sixth device layer DL6 may have a configuration similar to that of the second device layer DL2 discussed with reference to FIGS. 1 and 2. In comparison with the second device layer DL2, the sixth device layer DL6 may further include a second passivation layer 620. The sixth device layer DL6 may include a second semiconductor chip 300, a second dielectric layer 420, a second etch-stop layer 520, and the second passivation layer 620.

The second semiconductor chip 300 may be provided. The second etch-stop layer 520 may conformally cover lateral surfaces and a top surface of the first semiconductor chip 200 and the top surface of the first passivation layer 610. On the second etch-stop layer 520, the second dielectric layer 420 may surround the second semiconductor chip 300. A top surface of the second dielectric layer 420 may be substantially flat and coplanar with the top surface of the second etch-stop layer 520 positioned on the second semiconductor chip 300. The second dielectric layer 420 may have a thermal expansion coefficient greater than that of the buffer semiconductor chip 100. The second passivation layer 620 may be disposed on the second semiconductor chip 300 and the second dielectric layer 420. The second passivation layer 620 may cover the top surface of the second dielectric layer 420. Above of the second semiconductor chip 300, the second passivation layer 620 may cover the top surface of the second etch-stop layer 520. A third backside pad 340 of the second semiconductor chip 300 may penetrate the second etch-stop layer 520 and the second passivation layer 620. The third backside pad 340 may be exposed on a top surface of the second passivation layer 620. A top surface of the third backside pad 340 may be substantially flat and coplanar with the top surface of the second passivation layer 620.

A bottom surface of the sixth device layer DL6 may be in contact with a top surface of the fifth device layer DL5. A bottom surface of each of the second etch-stop layer 520 and the second semiconductor chip 300 in the sixth device layer DL6 may be in contact with the top surface of the first passivation layer 610.

The second semiconductor chip 300 may be mounted on the first semiconductor chip 200. The second backside pad 240 of the first semiconductor chip 200 may be vertically aligned with the third front pad 326 of the second semiconductor chip 300. The fifth device layer DL5 and the sixth device layer DL6 may be in contact with each other to connect the second backside pad 240 and the third front pad 326. The second backside pad 240 and the third front pad 326 may constitute an intermetallic hybrid bonding.

Neighboring third chip structures CS3 may be connected to each other. For example, the third backside pad 340 of the second semiconductor chip 300 in an underlying second chip structure CS2 may be vertically aligned with the second front pad 226 of the first semiconductor chip 200 in an overlying second chip structure CS2. Neighboring second chip structures CS2 may be in contact with each other to connect the third backside pad 340 and the second front pad 226 to each other. The third backside pad 340 and the second front pad 226 may constitute an intermetallic hybrid bonding.

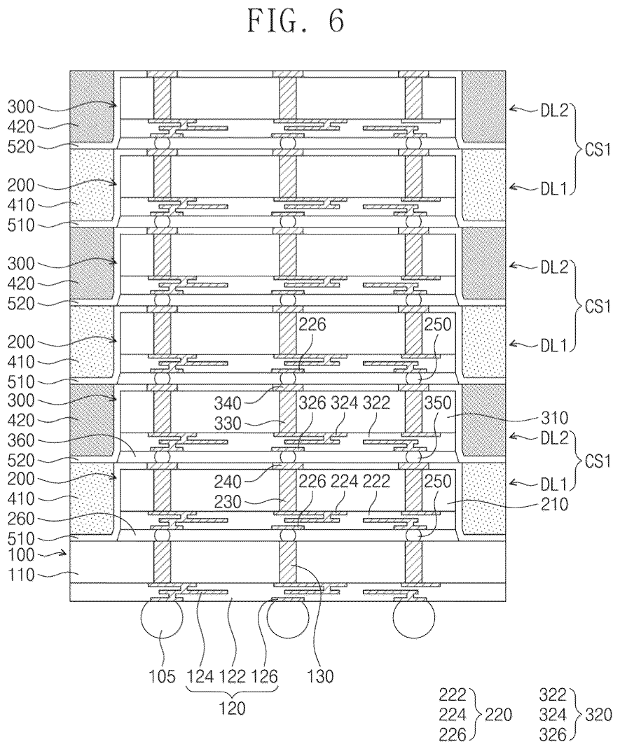

FIG. 6 illustrates a cross-sectional view showing a semiconductor package according to one or more embodiments of the present disclosure.

Referring to FIG. 6, first chip structures CS1 may be stacked on a buffer semiconductor chip 100. Each of the first chip structures CS1 may include a first device layer DL1 and a second device layer DL2 on the first device layer DL1.

FIGS. 1 to 5 depict that the second backside pad 240 of the first semiconductor chip 200 and the third front pad 326 of the second semiconductor chip 300 may be bonded through an intermetallic hybrid bonding, but the present disclosure is not limited thereto.

Referring still to FIG. 6, the second semiconductor chip 300 may be flip-chip mounted on the first semiconductor chip 200. A second chip terminal 350 may be provided on the third front pad 326 of the second semiconductor chip 300. The second chip terminal 350 may connect the second backside pad 240 and the third front pad 326 to each other. The second chip terminals 350 may include solder balls or solder bumps. A second inter-chip underfill layer 360 may be provided between the second semiconductor chip 300 and the first etch-stop layer 510 of the first device layer DL1. The second inter-chip underfill layer 360 may surround the second chip terminals 350, while filling a space between the first etch-stop layer 510 and the second semiconductor chip 300.

The second etch-stop layer 520 of the second device layer DL2 may surround the second semiconductor chip 300 and the second inter-chip underfill layer 360. A bottom surface of the second etch-stop layer 520 may be substantially flat and coplanar with the bottom surface of the second inter-chip underfill layer 360.

Neighboring first chip structures CS1 may be in contact with each other. The first device layer DL1 of an overlying first chip structure CS1 may be flip-chip mounted on the second device layer DL2 of an underlying first chip structure CS1. A first chip terminal 250 may be provided on the second front pad 226 of the first semiconductor chip 200 in an overlying first chip structure CS1. The first chip terminal 250 may connect the second front pad 226 to the third backside pad 340 of the second semiconductor chip 300 in an underlying first chip structure CS1. The first chip terminal 250 may include a solder ball or a solder bump. A first inter-chip underfill layer 260 may be provided between the second etch-stop layer 520 of an underlying first chip structure CS1 and the first semiconductor chip 200 of an overlying first chip structure CS1. The first inter-chip underfill layer 260 may surround the first chip terminal 250, while filling a space between the second etch-stop layer 520 and the first semiconductor chip 200.

The first etch-stop layer 510 may surround the first semiconductor chip 200 and the first inter-chip underfill layer 260. A bottom surface of the first etch-stop layer 510 may be substantially flat and coplanar with the bottom surface of the first inter-chip underfill layer 260.

The first device layer DL1 of the lowermost first chip structure CS1 may be mounted on the buffer semiconductor chip 100. For example, the first chip terminal 250 may be provided on the second front pad 226 of the first semiconductor chip 200 in the lowermost first chip structure CS1. The first chip terminal 250 may connect the second front pad 226 to the first through via 130 of the buffer semiconductor chip 100. The first inter-chip underfill layer 260 may be provided between the first semiconductor chip 200 and the buffer semiconductor chip 100.

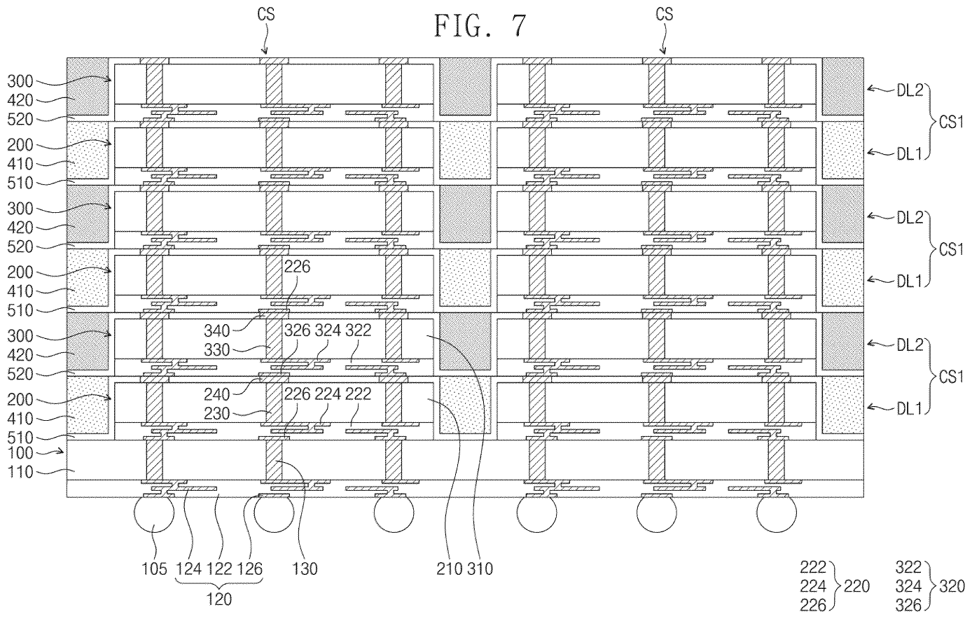

FIG. 7 illustrates a cross-sectional view showing a semiconductor package according to one or more embodiments of the present disclosure.

Referring to FIG. 7, first chip structures CS1 may be stacked on a buffer semiconductor chip 100. Each of the first chip structures CS1 may include a first device layer DL1 and a second device layer DL2 on the first device layer DL1.

The first device layers DL1 may include a plurality of first semiconductor chips 200. The second semiconductor chips DL2 may include a plurality of second semiconductor chips 300. The second semiconductor chips 300 may be correspondingly disposed on the first semiconductor chips 200. For example, a semiconductor package may include a plurality of chip stacks CS disposed on the buffer semiconductor chip 100, and each of the chip stacks CS may include the first semiconductor chips 200 and the second semiconductor chips 300 that are alternately stacked on the buffer semiconductor chip 100. FIG. 7 depicts a semiconductor package having two chip stacks CS, but the present disclosure is not limited thereto. A semiconductor package according to one or more embodiments of the present disclosure may include three or more chip stacks CS disposed on the buffer semiconductor chip 100.

The first etch-stop layer 510 of the first device layer DL1 may conformally cover the first semiconductor chips 200, and the first dielectric layer 410 may surround the first semiconductor chips 200. The second etch-stop layer 520 of the second device layer DL2 may conformally cover the second semiconductor chips 300, and the second dielectric layer 420 may surround the second semiconductor chips 300.

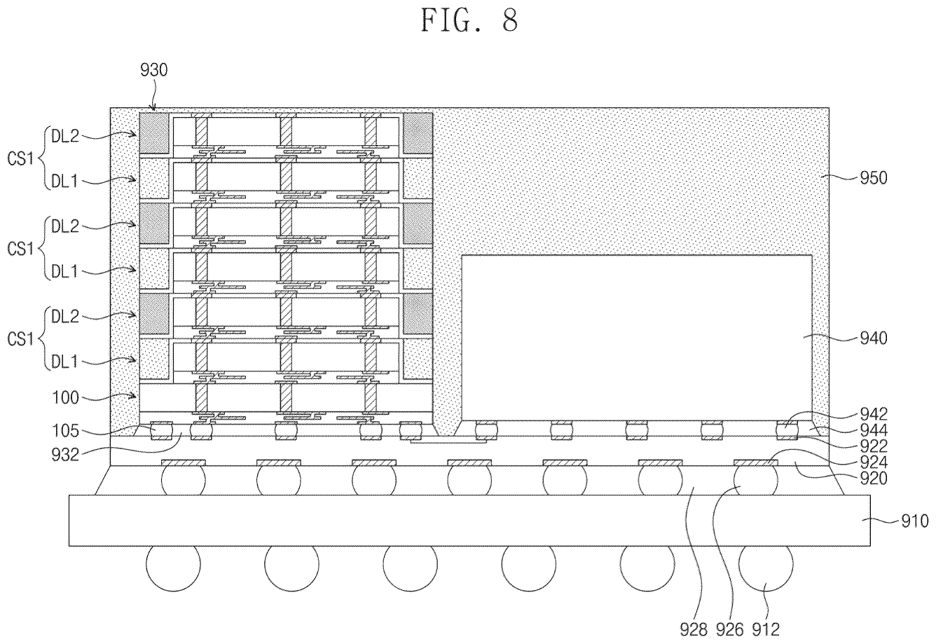

FIG. 8 illustrates a cross-sectional view showing a semiconductor module according to one or more embodiments of the present disclosure.

Referring to FIG. 8, a semiconductor module may be, for example, a memory module including a module substrate 910, a chip stack package 930 and a graphic processing unit (GPU) 940 that are mounted on the module substrate 910, and a molding layer 950 that covers the chip stack package 930 and the graphic processing unit 940. The semiconductor module may further include an interposer 920 provided on the module substrate 910.

The module substrate 910 may be provided. The module substrate 910 may include a printed circuit board (PCB) having a signal pattern on a top surface thereof.

The module substrate 910 may be provided with module terminals 912 thereunder. The module substrate 910 may include solder balls or solder bumps, and based on type and arrangement of the module terminals 912, the semiconductor module may be provided in the shape of one of a ball grid array (BGA) type, a fine ball-grid array (FBGA) type, and a land grid array (LGA) type.

The interposer 920 may be provided on the module substrate 910. The interposer 920 may include first substrate pads 922 exposed on a top surface of the interposer 920 and second substrate pads 924 exposed on a bottom surface of the interposer 920. The interposer 920 may redistribute the chip stack package 930 and the graphic processing unit 940. The interposer 920 may be flip-chip mounted on the module substrate 910. For example, the interposer 920 may be mounted on the module substrate 910 through substrate terminals 926 provided on the second substrate pads 924. The substrate terminals 926 may include solder balls or solder bumps. A first underfill layer 928 may be provided between the module substrate 910 and the interposer 920.

The chip stack package 930 may be disposed on the interposer 920. The chip stack package 930 may have a structure the same as or similar to that of the semiconductor package discussed with reference to FIGS. 1 to 7. For example, the chip stack package 930 may include the first chip structures CS1 stacked on the buffer semiconductor chip 100, and each of the first chip structures CS1 may include the first device layer DL1 and the second device layer DL2 stacked on the first device layer DL1. The first dielectric layer (see 410 of FIG. 1) of the first device layer DL1 may have a thermal expansion coefficient less than that of the buffer semiconductor chip 100. The second dielectric layer (see 420 of FIG. 1) of the second device layer DL2 may have a thermal expansion coefficient greater than that of the buffer semiconductor chip 100.

The chip stack package 930 may be mounted on the interposer 920. For example, the chip stack package 930 may be coupled to the first substrate pads 922 of the interposer 920 through the external terminals 105 of the buffer semiconductor chip 100. A second underfill layer 932 may be provided between the chip stack package 930 and the interposer 920. The second underfill layer 932 may surround the external terminals 105 of the base semiconductor chip 100, while filling a space between the interposer 920 and the base semiconductor chip 100.

The graphic processing unit 940 may be disposed on the interposer 920. The graphic processing unit 940 may be disposed spaced apart from the chip stack package 930. A thickness of the graphic processing unit 940 may be greater than those of semiconductor chips 100 and 200 of the chip stack package 930. The graphic processing unit 940 may include a logic circuit. For example, the graphic processing unit 940 may be a logic chip. The graphic processing unit 940 may be provided with bumps 942 on a bottom surface thereof. For example, the graphic processing unit 940 may be coupled through the bumps 942 to the first substrate pads 922 of the interposer 920. A third underfill layer 944 may be provided between the interposer 920 and the graphic processing unit 940. The third underfill layer 944 may surround the bumps 942, while filling a space between the interposer 920 and the graphic processing unit 940.

The molding layer 950 may be provided on the interposer 920. The molding layer 950 may cover the top surface of the interposer 920. The molding layer 950 may encapsulate the chip stack package 930 and the graphic processing unit 940. A top surface of the molding layer 950 may be located at the same level as that of a top surface of the chip stack package 930. The molding layer 950 may include a dielectric material. For example, the molding layer 950 may include an epoxy molding compound (EMC).

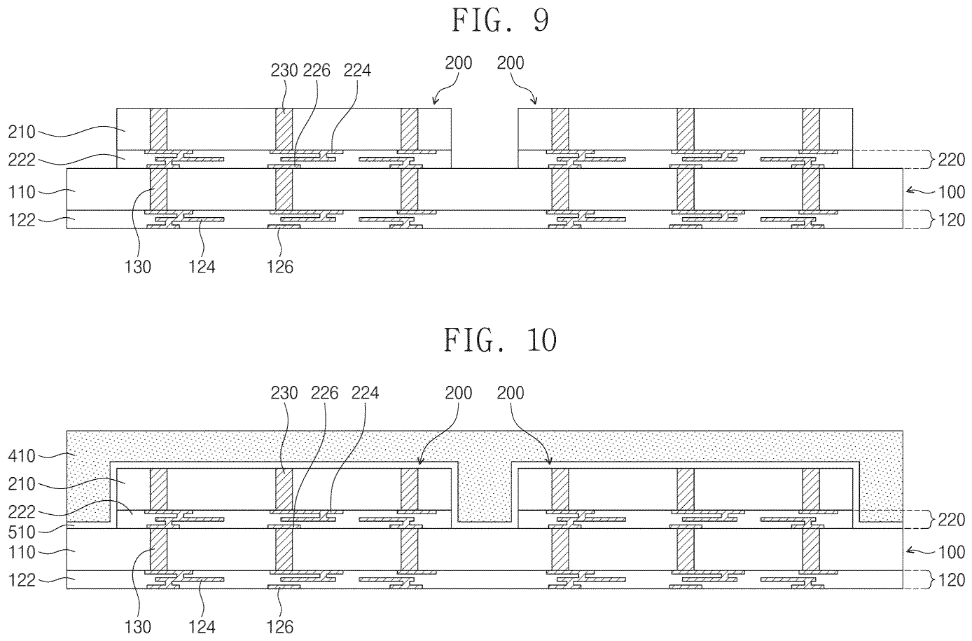

FIGS. 9 to 17 illustrate cross-sectional views showing a method of fabricating a semiconductor package according to one or more embodiments of the present disclosure.

Referring to FIG. 9, buffer semiconductor chips 100 may be formed. The buffer semiconductor chips 100 may be substantially the same as or similar to the buffer semiconductor chip 100 discussed with reference to FIGS. 1 to 7. For example, the buffer semiconductor chips 100 may each include a first base layer 110, a first circuit layer 120 provided on a front surface of the first base layer 110, and a first through via 130 that penetrates the first base layer 110. The buffer semiconductor chips 100 may be formed on a single wafer. For example, an integrated device or integrated circuits may be formed on a front surface of a semiconductor wafer, forming on the front surface of the semiconductor wafer the first circuit layer 120 connected to the integrated device or the integrated circuits, forming through holes on a rear surface of the semiconductor wafer, and then filling the through holes with a conductive material to form the first through via 130 connected to the first circuit layer 120.

The buffer semiconductor chips 100 or the semiconductor wafer including the buffer semiconductor chips 100 may be provided on a carrier substrate. The carrier substrate may be a dielectric substrate including glass or polymer, or may be a conductive substrate including metal.

A first semiconductor chip 200 may be manufactured. The first semiconductor chip 200 may be substantially the same as or similar to the first semiconductor chip 200 discussed with reference to FIGS. 1 to 7. For example, the first semiconductor chip 200 may include a second base layer 210, a second circuit layer 220 provided on a front surface of the second base layer 210, and a second through via 230 that penetrates the second base layer 210. For example, an integrated device or integrated circuits may be formed on a front surface of a semiconductor wafer, forming on the front surface of the semiconductor wafer the second circuit layer 220 connected to the integrated device or the integrated circuits, forming through holes on a rear surface of the semiconductor wafer, and then filling the through holes with a conductive material to form the second through via 230 connected to the second circuit layer 220. Afterwards, the semiconductor wafer may undergo a sawing process along a sawing line to divide the first semiconductor chip 200 into individual first semiconductor chips 200 separated from each other.

Each of the first semiconductor chips 200 may be bonded to one of the buffer semiconductor chips 100. The first semiconductor chips 200 and the buffer semiconductor chips 100 may be bonded in a chip-to-wafer shape. The first semiconductor chips 200 may be disposed on the buffer semiconductor chips 100. For example, active surfaces of the first semiconductor chips 200 may be directed toward an inactive surface of one of the buffer semiconductor chips 100. The first semiconductor chips 200 may be aligned on the buffer semiconductor chips 100 to vertically align a first through via 130 of the buffer semiconductor chip 100 with a second front pad 226 of the first semiconductor chip 200.

An annealing process may be performed on the first semiconductor chips 200 and the buffer semiconductor chips 100. The annealing process may bond the first through via 130 and the second front pad 226 to each other. For example, the first through via 130 and the second front pad 226 may be bonded to constitute a single unitary piece. The bonding between the first through via 130 and the second front pad 226 may be automatically performed. For example, the first through via 130 and the second front pad 226 may be formed of the same material (e.g., copper (Cu)), and may be bonded to each other by an intermetallic hybrid bonding process resulting from surface activation at an interface between the first through via 130 and the second front pad 226 that are in contact with each other. In the bonding process for the first semiconductor chips 200 and the buffer semiconductor chips 100, for easy bonding, the first semiconductor chips 200 may be densely adhered to or pressed against the buffer semiconductor chips 100.

Referring to FIG. 10, a first etch-stop layer 510 may be formed on the buffer semiconductor chips 100. The first etch-stop layer 510 may be formed to conformally cover the buffer semiconductor chips 100 and the first semiconductor chips 200. For example, the first etch-stop layer 510 may conformally cover top surfaces of the buffer semiconductor chips 100, and may also conformally cover lateral surfaces and top surfaces of the first semiconductor chips 200.

A first dielectric layer 410 may be formed on the first etch-stop layer 510. For example, on the first etch-stop layer 510, a dielectric material covering the first semiconductor chips 200 may be deposited to form the first dielectric layer 410.

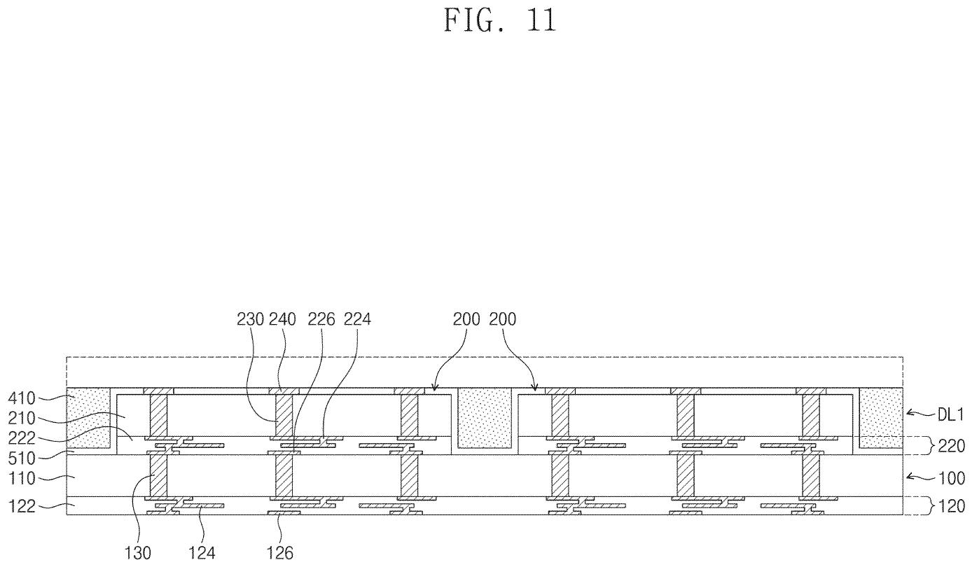

Referring to FIG. 11, a portion of the first dielectric layer 410 may be removed. For example, the first dielectric layer 410 may become thinned. In this case, the first dielectric layer 410 may undergo on its top surface a planarization process such as a grinding process or a chemical mechanical polishing (CMP) process. The grinding process or the chemical mechanical polishing process may continue until a top surface of the first etch-stop layer 510 is exposed. The top surface of the first etch-stop layer 510 and the top surface of the first dielectric layer 410 may be substantially flat and coplanar with each other. As discussed above, a first device layer DL1 may be formed which includes the first semiconductor chips 200, the first dielectric layer 410, and the first etch-stop layer 510.

The first etch-stop layer 510 may be patterned to form openings that expose the second through vias of the first semiconductor chips 200. The openings may be filled with a conductive material to form second backside pads 240 of the first semiconductor chips 200.

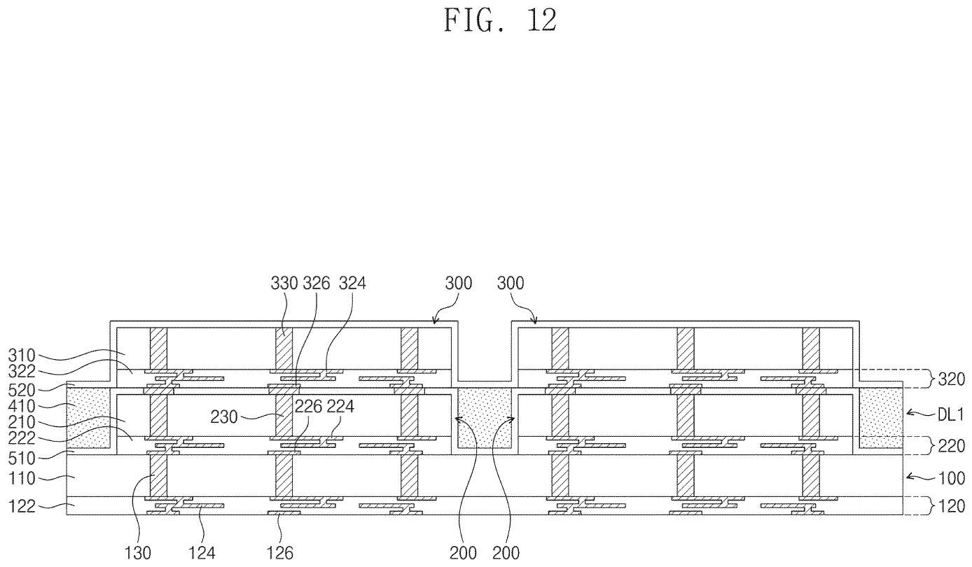

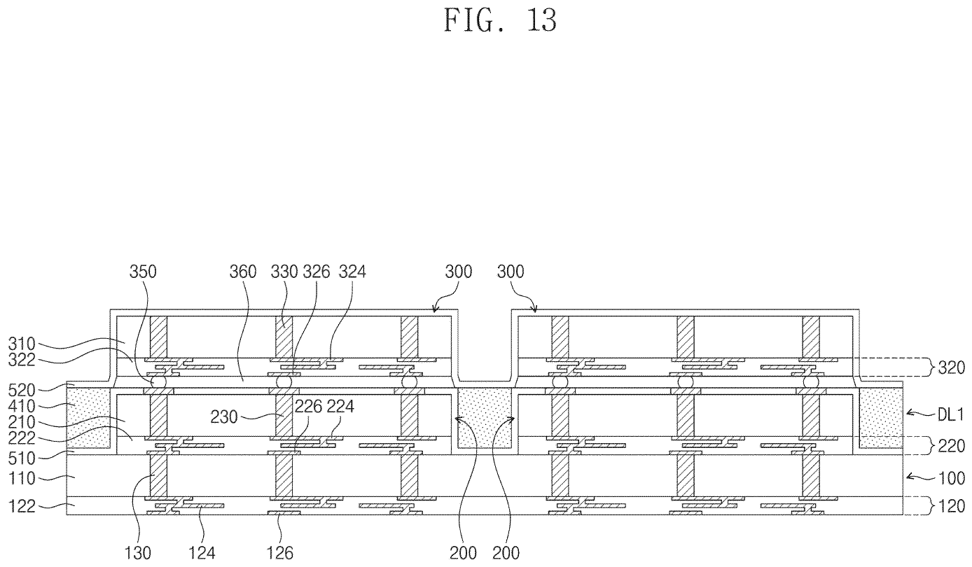

Referring to FIG. 12, a second semiconductor chip 300 may be manufactured. The second semiconductor chip 300 may be substantially the same as or similar to the second semiconductor chip 300 discussed with reference to FIGS. 1 to 7. For example, the second semiconductor chip 300 may include a third base layer 310, a third circuit layer 320 provided on a front surface of the third base layer 310, and a third through via 330 that penetrates the third base layer 310. For example, an integrated device or integrated circuits may be formed on a front surface of a semiconductor wafer, forming on the front surface of the semiconductor wafer the third circuit layer 320 connected to the integrated device or the integrated circuits, forming through holes on a rear surface of the semiconductor wafer, and then filling the through holes with a conductive material to form the third through via 330 connected to the third circuit layer 320. Afterwards, the semiconductor wafer may undergo a sawing process along a sawing line to divide the second semiconductor chip 300 into individual second semiconductor chips 300 separated from each other.

Each of the second semiconductor chips 300 may be bonded onto one of the first semiconductor chips 200. The second semiconductor chips 300 and the first semiconductor chips 200 may be bonded in a chip-to-chip shape. The second semiconductor chips 300 may be disposed on the first semiconductor chips 200. For example, active surfaces of the second semiconductor chips 300 may be directed toward an inactive surface of one of the first semiconductor chips 200. The second semiconductor chips 300 may be aligned on the first semiconductor chips 200 to vertically align second backside pads 240 of the first semiconductor chips 200 with third front pads 326 of the second semiconductor chips 300.

An annealing process may be performed on the second semiconductor chips 300 and the first semiconductor chips 200. The annealing process may bond the second backside pad 240 and the third front pad 326 to each other. For example, the second backside pad 240 and the third front pad 326 may be bonded to constitute a single unitary piece. The bonding of second backside pad 240 and the third front pad 326 may be automatically performed. For example, the second backside pad 240 and the third front pad 326 may be formed of the same material (e.g., copper (Cu)), and may be bonded to each other by an intermetallic hybrid bonding process resulting from surface activation at an interface between the second backside pad 240 and the third front pad 326 that are in contact with each other. In the bonding process for the second semiconductor chips 300 and the first semiconductor chips 200, for easy bonding, the second semiconductor chips 300 may be densely adhered to or pressed against the first semiconductor chips 200.

Referring to FIG. 13, a second etch-stop layer 520 may be formed on the first device layer DL1. The second etch-stop layer 520 may be formed to conformally cover the first device layer DL1 and the second semiconductor chips 300. For example, the second etch-stop layer 520 may conformally cover a top surface of the first device layer DL1, and may also conformally cover lateral surfaces and top surfaces of the second semiconductor chips 300.

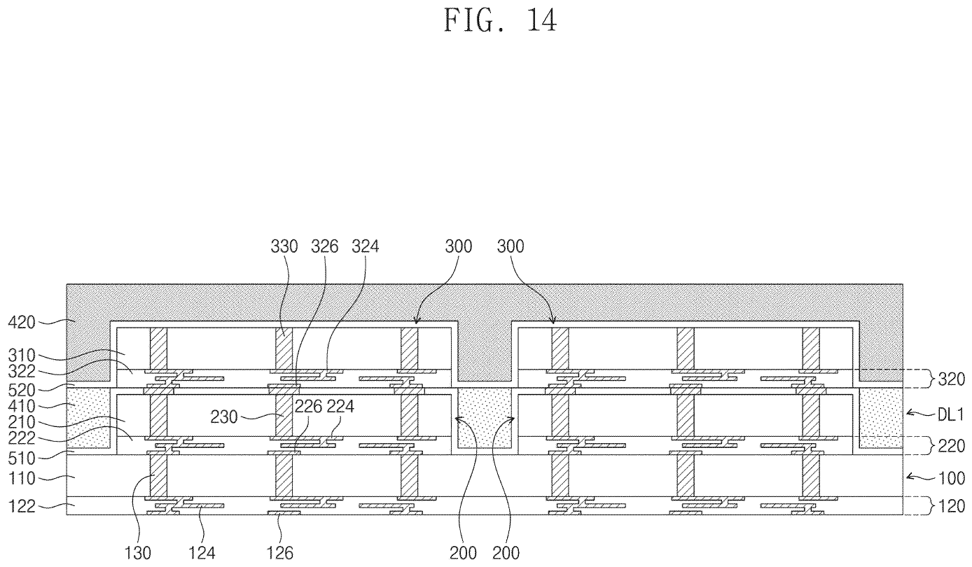

Referring to FIG. 14, a second dielectric layer 420 may be formed on the second etch-stop layer 520. For example, on the second etch-stop layer 520, a dielectric material covering the second semiconductor chips 300 may be deposited to form the second dielectric layer 420.

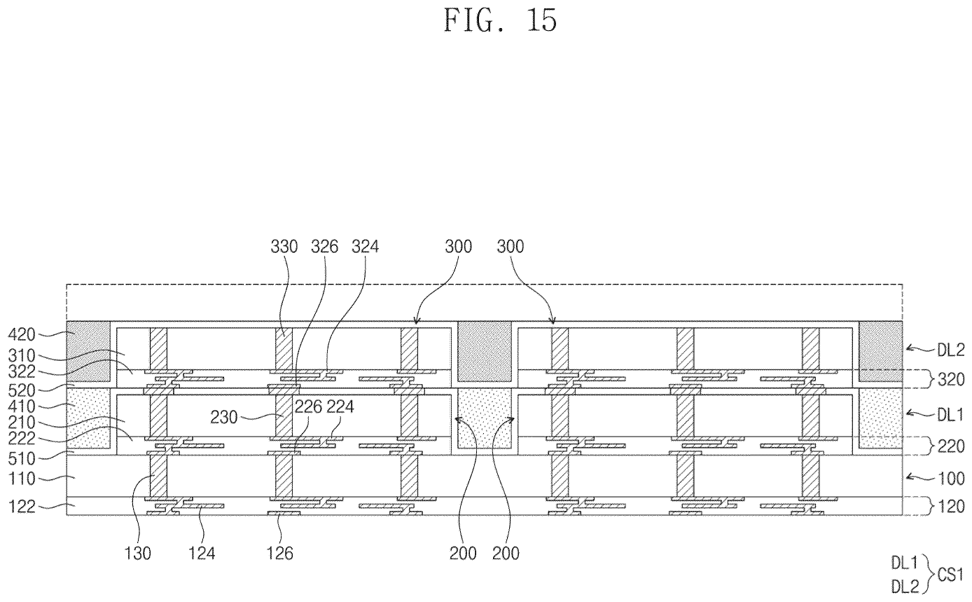

Referring to FIG. 15, a portion of the second dielectric layer 420 may be removed. For example, the second dielectric layer 420 may become thinned. In this case, the second dielectric layer 420 may undergo on its top surface a planarization process such as a grinding process or a chemical mechanical polishing (CMP) process. The grinding process or the chemical mechanical polishing process may continue until a top surface of the second etch-stop layer 520 is exposed. The top surface of the second etch-stop layer 520 and the top surface of the second dielectric layer 420 may be substantially flat and coplanar with each other. As discussed above, a second device layer DL2 may be formed which includes the second semiconductor chips 300, the second dielectric layer 420, and the second etch-stop layer 520.

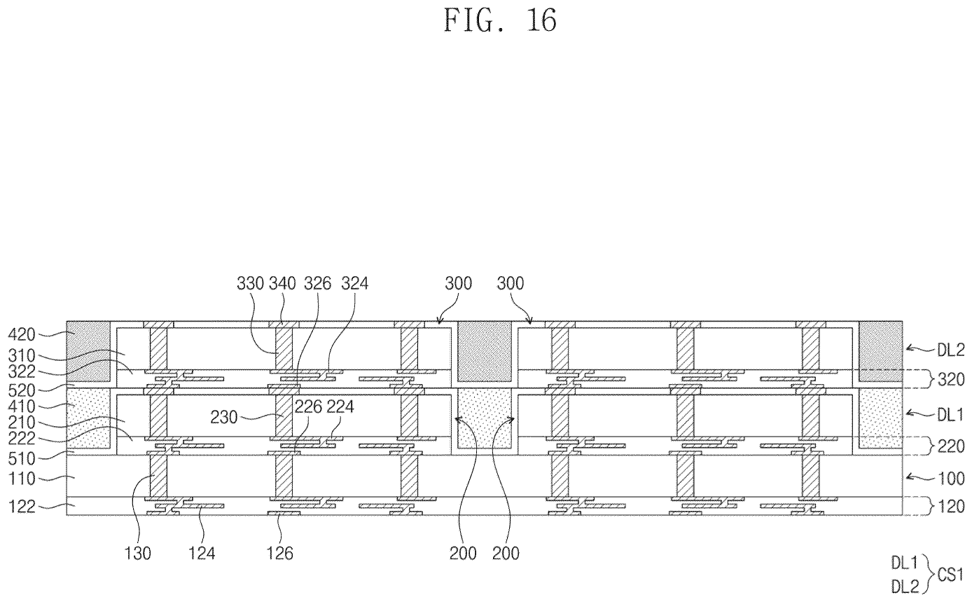

Referring to FIG. 16, the second etch-stop layer 520 may be patterned to form openings that expose the third through vias 330 of the second semiconductor chips 300. The openings may be filled with a conductive material to form third backside pads 340 of the second semiconductor chips 300.

Thus, it may be possible to form a first chip structure CS1 including the first device layer DL1 and the second device layer DL2.

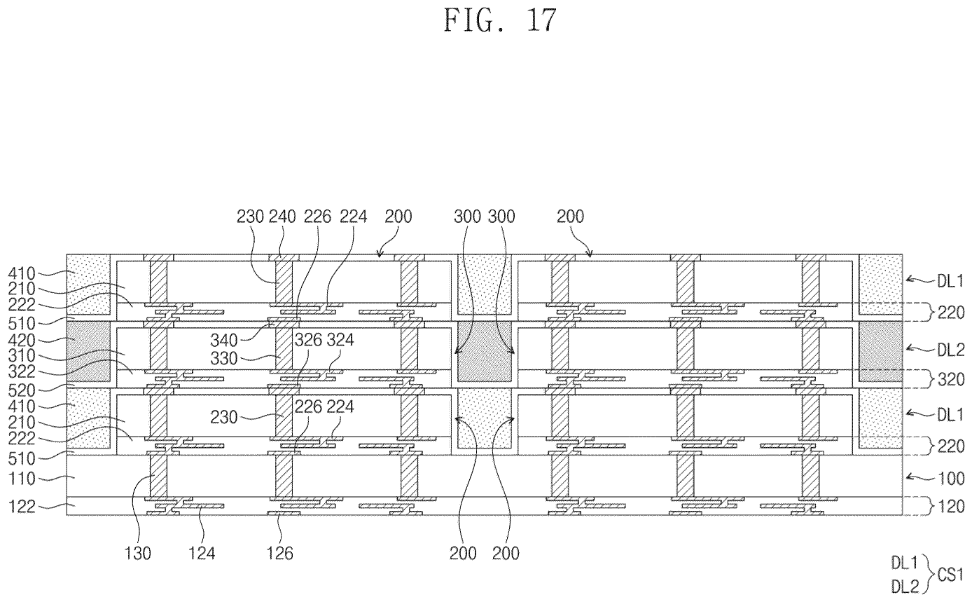

A plurality of first chip structures CS1 may be formed on the first chip structure CS1. The formation of the first chip structures CS1 may be substantially the same as or similar to that discussed with reference to FIGS. 9 to 16. Referring to FIG. 17, first semiconductor chips 200 may be disposed on the second semiconductor chips 300 of the second device layer DL2 in the first chip structure CS1. Each of the second semiconductor chips 300 may be bonded onto one of the first semiconductor chips 200. A first etch-stop layer 510 may be formed on the second device layer DL2. The first etch-stop layer 510 may be formed to conformally cover the second device layer DL2 and the first semiconductor chips 200. A first dielectric layer 410 may be formed on the first etch-stop layer 510, covering the first semiconductor chips 200. A portion of the first dielectric layer 410 may be removed to expose a top surface of the first etch-stop layer 510. A first device layer DL1 may be formed on the first chip structure CS1. Thereafter, the processes discussed with reference to FIGS. 12 to 16 may be performed to form a second device layer DL2.

Referring to FIG. 1, a sawing process may be performed, if necessary, on the buffer semiconductor chip 100 and the first chip structures CS1. The sawing process may form individual semiconductor packages separated from each other.

An external terminal 105 may be provided on the first front pad 126 of the buffer semiconductor chip 100.

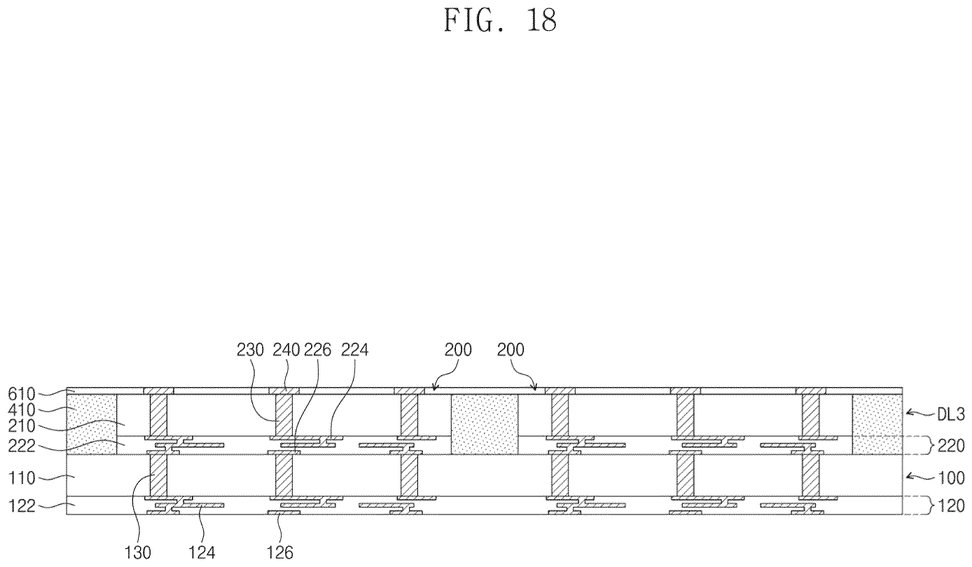

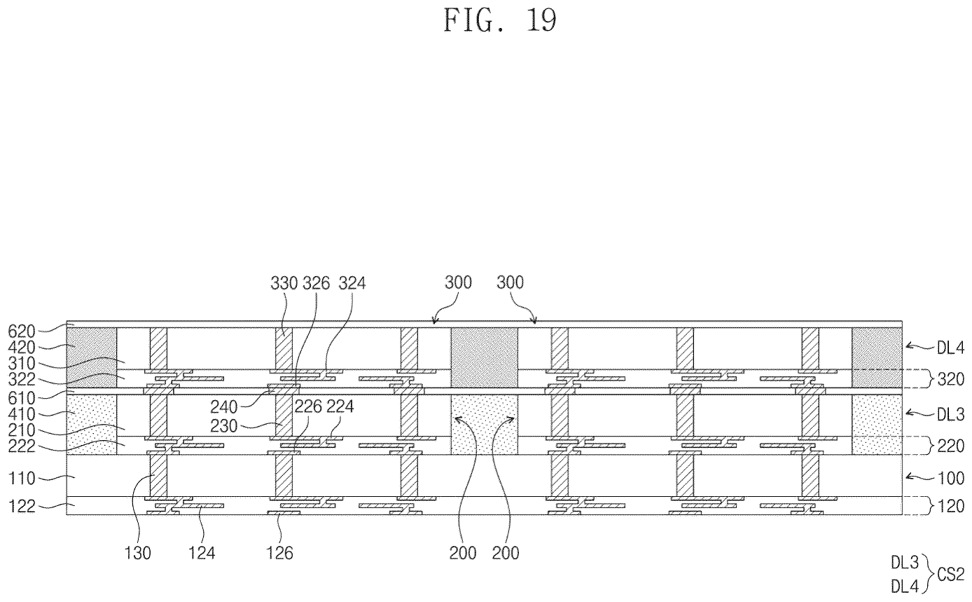

FIGS. 18 and 19 illustrate cross-sectional views showing a method of fabricating a semiconductor package according to one or more embodiments of the present disclosure.

Referring to FIG. 18, on a resultant structure of FIG. 9, a first dielectric layer 410 may be formed on the buffer semiconductor chip 100. For example, on the buffer semiconductor chip 100, a dielectric material covering the first semiconductor chips 200 may be deposited to form the first dielectric layer 410.

A portion of the first dielectric layer 410 may be removed. For example, the first dielectric layer 410 may become thinned. In this case, the first dielectric layer 410 may undergo on its top surface a planarization process such as a grinding process or a chemical mechanical polishing (CMP) process. The grinding process or the chemical mechanical polishing process may continue until top surfaces of the first semiconductor chips 200 are exposed.

A first passivation layer 610 may be formed on the first dielectric layer 410 and the first semiconductor chips 200. The first passivation layer 610 may be formed to cover a top surface of the first dielectric layer 410 and the top surfaces of the first semiconductor chips 200.

The first passivation layer 610 may be patterned to form openings that expose the second through vias 230 of the first semiconductor chips 200. The openings may be filled with a conductive material to form second backside pads 240 of the first semiconductor chips 200. Thus, a third device layer DL3 may be formed which includes the first semiconductor chips 200, the first dielectric layer 410, and the first passivation layer 610.

Referring to FIG. 19, second semiconductor chips 300 may be provided. Each of the second semiconductor chips 300 may be bonded onto one of the first semiconductor chips 200. The second backside pads 240 of the first semiconductor chips 200 may be connected to third front pads 326 of the second semiconductor chips 300.

A second dielectric layer 420 may be formed on the third device layer DL3. For example, on the third device layer DL3, a dielectric material covering the second semiconductor chips 300 may be deposited to form the second dielectric layer 420.

A portion of the second dielectric layer 420 may be removed. For example, the second dielectric layer 420 may become thinned. The thinning process may continue until top surfaces of the second semiconductor chips 300 are exposed.

A second passivation layer 620 may be formed on the second dielectric layer 420 and the second semiconductor chips 300. The second passivation layer 620 may be formed to cover a top surface of the second dielectric layer 420 and the top surfaces of the second semiconductor chips 300.

The second passivation layer 620 may be patterned to form openings that expose the third through vias 330 of the second semiconductor chips 300. The openings may be filled with a conductive material to form third backside pads 340 of the second semiconductor chips 300. Thus, a fourth device layer DL4 may be formed which includes the second semiconductor chips 300, the second dielectric layer 420, and the second passivation layer 620. The third device layer DL3 and the fourth device layer DL4 may constitute a second chip structure CS2.

A plurality of second chip structures CS2 may be formed on the second chip structure CS2. The formation of the second chip structures CS2 may be substantially the same as or similar to that discussed with reference to FIGS. 18 and 19.

Referring to FIG. 3, a sawing process may be performed, if necessary, on the buffer semiconductor chip 100 and the second chip structures CS2. The sawing process may form individual semiconductor packages separated from each other.

An external terminal 105 may be provided on the first front pad 126 of the buffer semiconductor chip 100.

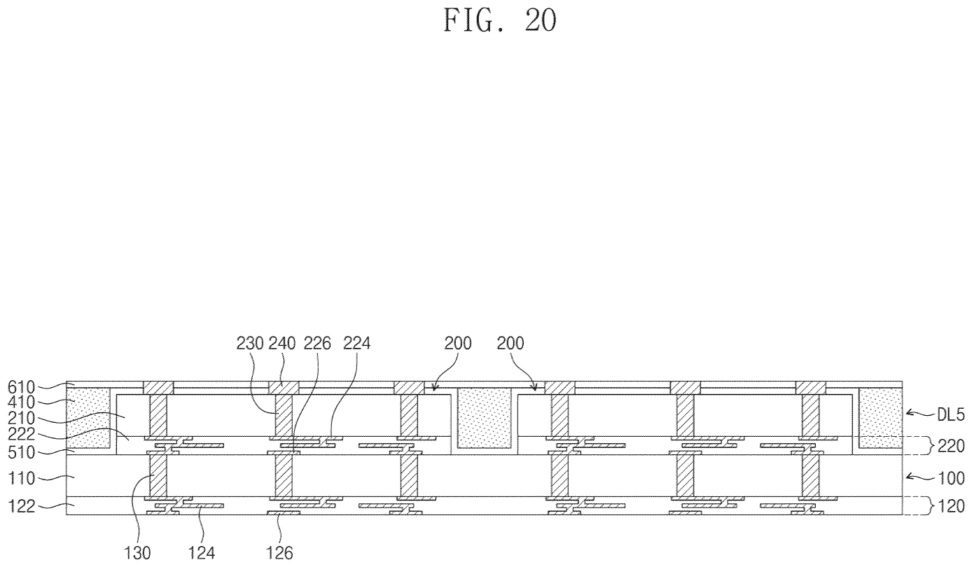

FIG. 20 illustrates a cross-sectional view showing a method of fabricating a semiconductor package according to one or more embodiments of the present disclosure.

Referring to FIG. 20, on a resultant structure of FIG. 10, a portion of the first dielectric layer 410 may be removed. For example, the first dielectric layer 410 may become thinned. The thinning process may continue until a top surface of the first etch-stop layer 510 is exposed.

A first passivation layer 610 may be formed on the first dielectric layer 410 and the first etch-stop layer 510. The first passivation layer 610 may be formed to cover a top surface of the first dielectric layer 410 and the top surface of the first etch-stop layer 510.

The first etch-stop layer 510 and the first passivation layer 610 may be patterned to form openings that expose the second through vias 230 of the first semiconductor chips 200. The openings may be filled with a conductive material to form second backside pads 240 of the first semiconductor chips 200. A fifth device layer DL5 may be formed which includes the first semiconductor chips 200, the first dielectric layer 410, the first etch-stop layer 510, and the first passivation layer 610.

Referring to FIG. 5, a sixth device layer DL6 may be formed on the fifth device layer DL5. The formation of the sixth device layer DL6 may be substantially the same as or similar to the formation of the fifth device layer DL5.

The fifth device layer DL5 and the sixth device layer DL6 may constitute a third chip structure CS3.

A plurality of third chip structures CS3 may be formed on the third chip structure CS3.

A sawing process may be performed, if necessary, on the buffer semiconductor chip 100 and the third chip structures CS3. The sawing process may form individual semiconductor packages separated from each other.

An external terminal 105 may be provided on the first front pad 126 of the buffer semiconductor chip 100.

In a semiconductor package according to one or more embodiments of the present disclosure, as a buffer semiconductor chip is alternately stacked thereon with a first dielectric layer whose thermal expansion coefficient is less than that of the buffer semiconductor chip and a second dielectric layer whose thermal expansion coefficient is greater than that of the buffer semiconductor chip, it may be possible to suppress warpage of the semiconductor package. As a result, the semiconductor package may have increased structural stability.

Although the present disclosure has been described in connection with the one or more embodiments of the present disclosure illustrated in the accompanying drawings, it will be understood by one of ordinary skill in the art that variations in form and detail may be made therein without departing from the spirit and essential feature of the present disclosure. The above disclosed embodiments should thus be considered illustrative and not restrictive.

What is claimed is:

1. A semiconductor package comprising:
a substrate;
a first semiconductor chip on the substrate;
a first dielectric layer on the substrate and at least partially surrounding the first semiconductor chip;
a first passivation layer on a top surface of the first semiconductor chip and a top surface of the first dielectric layer;
a second semiconductor chip on the first passivation layer;
a first etch-stop layer on a top surface of the first passivation layer and on a top surface and a lateral surface of the second semiconductor chip; and
a second dielectric layer on the first etch-stop layer and at least partially surrounding the second semiconductor chip,
wherein a thermal expansion coefficient of the first dielectric layer is less than a thermal expansion coefficient of the substrate, and
wherein a thermal expansion coefficient of the second dielectric layer is greater than the thermal expansion coefficient of the substrate.

2. The semiconductor package of claim 1,
wherein the first dielectric layer comprises silicon oxide (SiO), and
wherein the second dielectric layer comprises silicon nitride (SiN).

3. The semiconductor package of claim 1,
wherein the first semiconductor chip comprises a first chip pad on the top surface of the first semiconductor chip,
wherein the first chip pad penetrates the first passivation layer and is exposed on the top surface of the first passivation layer, and
wherein the second semiconductor chip is on the first chip pad.

4. The semiconductor package of claim 3, wherein the second semiconductor chip is connected to the first semiconductor chip through a chip connection terminal between the second semiconductor chip and the first chip pad.

5. The semiconductor package of claim 3,
wherein the second semiconductor chip comprises a second chip pad on a bottom surface of the second semiconductor chip, and
wherein, on an interface between the first passivation layer and the second semiconductor chip, the first chip pad and the second chip pad are in contact with each other and constitute a single unitary piece.

6. The semiconductor package of claim 1, further comprising:
a third semiconductor chip on the first etch-stop layer;
a second etch-stop layer that covers a top surface of the second dielectric layer and a top surface and a lateral surface of the third semiconductor chip; and
a third dielectric layer on the second etch-stop layer and at least partially surrounding the third semiconductor chip,
wherein the third dielectric layer and the first dielectric layer comprises a same material.

7. The semiconductor package of claim 1, further comprising:
a second passivation layer on a top surface of the first etch-stop layer and a top surface of the second dielectric layer,
wherein the second semiconductor chip comprises a third chip pad on the top surface of the second semiconductor chip, and
wherein the third chip pad penetrates the second passivation layer and is exposed on a top surface of the second passivation layer.

8. The semiconductor package of claim 1,
wherein the top surface of the first semiconductor chip is substantially flat and coplanar with the top surface of the first dielectric layer, and
wherein a top surface of the first etch-stop layer is substantially flat and coplanar with a top surface of the second dielectric layer.

9. A semiconductor package comprising:
a substrate; and
a plurality of chip structures stacked on the substrate,
wherein each of the plurality of chip structures comprises:
a first semiconductor chip;
a first dielectric layer that at least partially surrounds the first semiconductor chip;
a second semiconductor chip on the first semiconductor chip;
a second dielectric layer on the first dielectric layer and at least partially surrounding the second semiconductor chip; and
a first etch-stop layer between the second dielectric layer and the first dielectric layer,
wherein the first dielectric layer comprises silicon oxide (SiO), and
wherein the second dielectric layer comprises silicon nitride (SiN).

10. The semiconductor package of claim 9,
wherein a thermal expansion coefficient of the first dielectric layer is less than a thermal expansion coefficient of the substrate, and
wherein a thermal expansion coefficient of the second dielectric layer is greater than the thermal expansion coefficient of the substrate.

11. The semiconductor package of claim 9,
wherein the first etch-stop layer is between the second semiconductor chip and the second dielectric layer, and
wherein the first etch-stop layer conformally covers a lateral surface of the second semiconductor chip and a top surface of the first dielectric layer.

12. The semiconductor package of claim 9,
wherein each of the plurality of chip structures further comprises a first passivation layer on a top surface of the first semiconductor chip and a top surface of the first dielectric layer, and
wherein the first etch-stop layer is on a top surface of the first passivation layer.

13. The semiconductor package of claim 12,
wherein the first semiconductor chip comprises a first chip pad on the top surface of the first semiconductor chip,
wherein the first chip pad penetrates the first passivation layer and is exposed on the top surface of the first passivation layer, and
wherein the second semiconductor chip is on the first chip pad.

14. The semiconductor package of claim 9,
wherein the first semiconductor chip comprises a first chip pad on a top surface of the first semiconductor chip,
wherein the second semiconductor chip comprises a second chip pad on a bottom surface of the second semiconductor chip, and
wherein the second semiconductor chip is connected to the first semiconductor chip through a chip connection terminal between the second chip pad and the first chip pad.

15. The semiconductor package of claim 9,
wherein the first semiconductor chip comprises a first chip pad on a top surface of the first semiconductor chip,
wherein the second semiconductor chip comprises a second chip pad on a bottom surface of the second semiconductor chip, and
wherein the first chip pad and the second chip pad are in contact with each other and constitute a single unitary piece.

16. The semiconductor package of claim 9, further comprising a second etch-stop layer between a first chip structure and a second chip structure among the plurality of chip structures,
wherein the first chip structure is on the substrate,
wherein the second chip structure is on the first chip structure,
wherein the first semiconductor chip of the second chip structure is on the second semiconductor chip of the first chip structure, and
wherein the second etch-stop layer is on the second dielectric layer of the first chip structure and the first dielectric layer of the second chip structure.

17. The semiconductor package of claim 9, wherein each of the plurality of chip structures further comprises a second passivation layer that covers a top surface of the second semiconductor chip and a top surface of the second dielectric layer.

18. A method of fabricating a semiconductor package, the method comprising:
placing a first semiconductor chip on a substrate;
forming on the substrate a first dielectric layer that at least partially surrounds the first semiconductor chip;
placing a second semiconductor chip on the first semiconductor chip;
forming a first etch-stop layer on a top surface of the second semiconductor chip and a top surface of the first dielectric layer;
forming on the first etch-stop layer a second dielectric layer on the first semiconductor chip and the first dielectric layer;
performing a thinning process on the second dielectric layer to expose the first etch-stop layer on the first semiconductor chip;
placing a third semiconductor chip on the second semiconductor chip;
forming a second etch-stop layer on a top surface and lateral surfaces of the third semiconductor chip and a top surface of the second dielectric layer; and
forming on the second etch-stop layer a third dielectric layer on the second semiconductor chip and the second dielectric layer,
wherein a thermal expansion coefficient of the first dielectric layer and a thermal expansion coefficient of the third dielectric layer are less than a thermal expansion coefficient of the substrate, and
wherein a thermal expansion coefficient of the second dielectric layer is greater than the thermal expansion coefficient of the substrate.

19. The method of claim 18,
wherein the first dielectric layer and the third dielectric layer comprise silicon oxide (SiO), and
wherein the second dielectric layer comprises silicon nitride (SiN).

20. The method of claim 18, further comprising:
after the thinning process, forming a passivation layer on the top surface of the second dielectric layer and a top surface of the first etch-stop layer; and
forming a chip pad that penetrates the first etch-stop layer and the passivation layer and is in connection with the second semiconductor chip,
wherein the third semiconductor chip is connected to the second semiconductor chip through the chip pad.
